(19) United States
(12) Patent Application Publication
(10) Pub. No.: US 2026/0190324 A1
(43) Pub. Date: Jul. 2, 2026

(54) SEMICONDUCTOR DEVICES

(71) Applicant: Samsung Electronics Co., Ltd., Suwon-si (KR)

(72) Inventors: TEAWON KIM, Suwon-si (KR); JIHYUN KHO, Suwon-si (KR); YURIM KIM, Suwon-si (KR); TAEWON KIM, Suwon-si (KR); YONG-SUK TAK, Suwon-si (KR); JINWON MA, Suwon-si (KR)

(21) Appl. No.: 19/361,106

(22) Filed: Oct. 17, 2025

(30) Foreign Application Priority Data
Dec. 26, 2024 (KR) 10-2024-0197538

(51) Int. Cl. H10B 12/00

(52) U.S. Cl. CPC H10B 12/315; H10B 12/05

(57) ABSTRACT

A semiconductor device includes a substrate; a bit line on the substrate, wherein the bit line extends in a first direction parallel with an upper surface of the substrate; a word line on the bit line, wherein the word line extends in a second direction parallel with the upper surface of the substrate; a pillar structure on the bit line, wherein the pillar structure extends through the word line and includes a semiconductor pattern and a gate insulating pattern between the semiconductor pattern and the word line; and a data storage pattern on the pillar structure, the semiconductor pattern includes a horizontal portion and a vertical portion, the horizontal portion is adjacent to the bit line, wherein the vertical portion is on the horizontal portion and extends in a third direction perpendicular to the upper surface of the substrate, and the semiconductor pattern has a hollow pillar shape.

### CROSS-REFERENCE TO RELATED APPLICATIONS

This U.S. non-provisional patent application claims priority under 35 U.S.C. § 119 to Korean Patent Application No. 10-2024-0197538, filed on Dec. 26, 2024, in the Korean Intellectual Property Office, the entire contents of which are hereby incorporated by reference.

### BACKGROUND

The present disclosure relates to semiconductor devices, and in particular, to semiconductor devices including a vertical channel transistor.

A semiconductor device may include an integrated circuit comprising metal-oxide-semiconductor field-effect transistors (MOS-FETs). To meet an increasing demand for the semiconductor device with a small pattern size and a reduced design rule, the MOS-FETs are being scaled down. The scale-down of the MOS-FETs may lead to deterioration in operation characteristics of the semiconductor device. Accordingly, a variety of studies are being conducted to overcome technical limitations associated with the scale-down of the semiconductor device and to provide high performance semiconductor device.

### SUMMARY

An embodiment of the inventive concept provides semiconductor devices with improved reliability and electrical characteristics.

According to an embodiment of the inventive concept, a semiconductor device may include a substrate; a bit line on the substrate, wherein the bit line extends in a first direction that is parallel with an upper surface of the substrate; a word line on the bit line, wherein the word line extends in a second direction that is parallel with the upper surface of the substrate and intersects the first direction; a pillar structure on the bit line, wherein the pillar structure extends through the word line and comprises a semiconductor pattern and a gate insulating pattern between the semiconductor pattern and the word line; and a data storage pattern on the pillar structure, wherein the semiconductor pattern comprises a horizontal portion and a vertical portion, wherein the horizontal portion is adjacent to the bit line, wherein the vertical portion is on the horizontal portion and extends in a third direction that is perpendicular to the upper surface of the substrate, and wherein the semiconductor pattern has a hollow pillar shape.

According to an embodiment of the inventive concept, a semiconductor device may include a substrate; a bit line on the substrate, wherein the bit line extends in a first direction that is parallel with an upper surface of the substrate; a word line on the bit line, wherein the word line extends in a second direction that is parallel with the upper surface of the substrate and intersects the first direction; a pillar structure on the bit line, wherein the pillar structure extends through the word line in a third direction that is perpendicular to the upper surface of the substrate; and a data storage pattern on the pillar structure, wherein the pillar structure comprises a center insulating pattern, a semiconductor pattern that extends around the center insulating pattern, and a gate insulating pattern that extends around the semiconductor pattern.

According to an embodiment of the inventive concept, a semiconductor device may include a bit line on a substrate, wherein the bit line extends in a first direction that is parallel with an upper surface of the substrate; a word line extending in a second direction that is parallel with the upper surface of the substrate, wherein the second direction intersects the first direction, and wherein the word line is spaced apart from the bit line in a third direction that is perpendicular to the upper surface of the substrate; a pillar structure extending into the word line in the third direction, wherein the pillar structure comprises a center insulating pattern, a semiconductor pattern that extends around the center insulating pattern, and a gate insulating pattern that extends around the semiconductor pattern; a landing pad on the pillar structure; a storage node contact between the landing pad and the semiconductor pattern; and a data storage pattern on the landing pad, wherein the semiconductor pattern comprises a horizontal portion between the center insulating pattern and the bit line and a vertical portion between the center insulating pattern and the gate insulating pattern.

### BRIEF DESCRIPTION OF THE DRAWINGS

FIG. 1 is a block diagram illustrating a semiconductor device according to an embodiment of the inventive concept.

FIGS. 2 and 3 are perspective views, each of which schematically illustrates a semiconductor device according to an embodiment of the inventive concept.

FIG. 4 is a plan view illustrating a semiconductor device according to an embodiment of the inventive concept.

FIG. 5 is a sectional view, which is taken along a line A-A′ of FIG. 4 to illustrate a semiconductor device according to an embodiment of the inventive concept.

FIG. 6 is a sectional view, which is taken along a line B-B′ of FIG. 4 to illustrate a semiconductor device according to an embodiment of the inventive concept.

FIG. 7 is a plan view, which is taken along a line C-C′ of FIG. 6 to illustrate a semiconductor device according to an embodiment of the inventive concept.

FIG. 8 is a plan view illustrating a semiconductor device according to an embodiment of the inventive concept.

FIG. 9 is a sectional view, which is taken along a line B-B′ of FIG. 8 to illustrate a semiconductor device according to an embodiment of the inventive concept.

FIG. 10 is a plan view illustrating a semiconductor device according to an embodiment of the inventive concept.

FIG. 11 is a sectional view, which is taken along a line A-A′ of FIG. 10 to illustrate a semiconductor device according to an embodiment of the inventive concept.

FIG. 12 is a plan view illustrating a semiconductor device according to an embodiment of the inventive concept.

FIG. 13 is a sectional view, which is taken along a line D-D′ of FIG. 12 to illustrate a semiconductor device according to an embodiment of the inventive concept.

FIG. 14 is a sectional view, which is taken along a line E-E′ of FIG. 12 to illustrate a semiconductor device according to an embodiment of the inventive concept.

FIG. 15 is a plan view, which is taken along a line F-F′ of FIG. 14 to illustrate a semiconductor device according to an embodiment of the inventive concept.

FIG. 16 is a plan view illustrating a semiconductor device according to an embodiment of the inventive concept.

FIG. 17 is a sectional view, which is taken along a line E-E′ of FIG. 16 to illustrate a semiconductor device according to an embodiment of the inventive concept.

FIG. 18 is a plan view illustrating a semiconductor device according to an embodiment of the inventive concept.

FIG. 19 is a sectional view, which is taken along a line D-D′ of FIG. 18 to illustrate a semiconductor device according to an embodiment of the inventive concept.

FIG. 20 is a perspective view illustrating a semiconductor device according to an embodiment of the inventive concept.

FIG. 21 is a sectional view, which is taken along a line I-I′ of FIG. 20 to illustrate a semiconductor device according to an embodiment of the inventive concept.

FIGS. 22 to 37 are diagrams illustrating a method of fabricating a semiconductor device, according to an embodiment of the inventive concept.

FIGS. 38 to 55 are diagrams illustrating a method of fabricating a semiconductor device, according to an embodiment of the inventive concept.

FIGS. 56 to 70 are diagrams illustrating a method of fabricating a semiconductor device, according to an embodiment of the inventive concept.

### DETAILED DESCRIPTION

Example embodiments of the inventive concept will now be described more fully with reference to the accompanying drawings, in which example embodiments are shown. Example embodiments of the inventive concept may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions may be exaggerated for clarity. Like reference numerals in the drawings may denote like elements unless clearly described otherwise, and thus their description may be omitted.

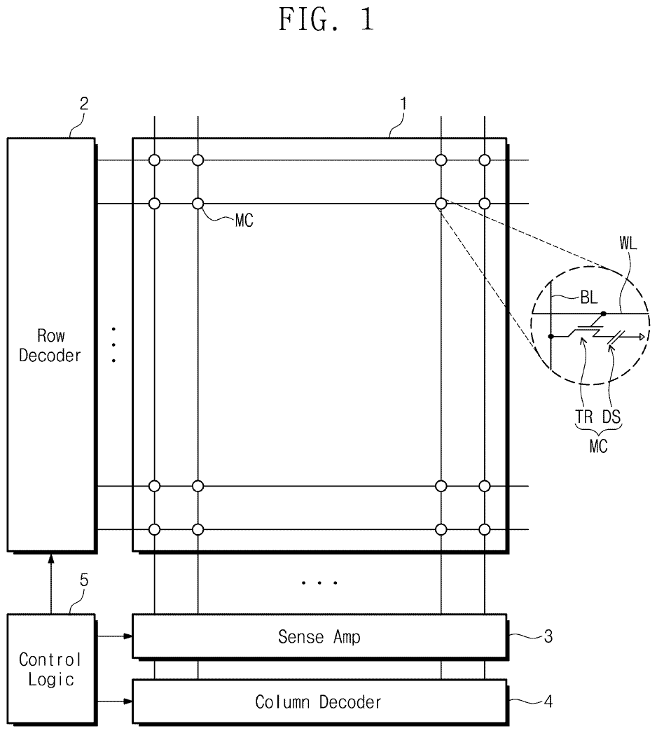

FIG. 1 is a block diagram illustrating a semiconductor device according to an embodiment of the inventive concept.

Referring to FIG. 1, a semiconductor device may include a memory cell array 1, a row decoder 2, a sense amplifier 3, a column decoder 4, and a control logic 5.

The memory cell array 1 may include a plurality of memory cells MC, which are two- or three-dimensionally arranged. Each of the memory cells MC may be provided between and (electrically) connected to a word line WL and a bit line BL, which are provided to cross each other. Each of the memory cells MC may include a selection element TR and a data storage device DS. The selection element TR and the data storage device DS may be (electrically) connected to each other. The selection element TR may be (electrically) connected to both the word line WL and the bit line BL. In other words, the selection element TR may be provided at an intersection of the word and bit lines WL and BL.

The selection element TR may include a field effect transistor. The data storage device DS may include a capacitor, a magnetic tunnel junction pattern, and/or a variable resistor. As an example, the selection element TR may be a transistor whose gate, source, and drain terminals are (electrically) connected to the word line WL, the bit line BL, and the data storage device DS, respectively. As used herein, the term “and/or” includes any and all combinations of one or more of the associated listed items.

The row decoder 2 may be configured to decode address information, which is input from the outside, and to select one of the word lines WL of the memory cell array 1, based on the decoded address information. The address information decoded by the row decoder 2 may be provided to a row driver (not shown), and in this case, the row driver may provide respective voltages to the selected one of the word lines WL and the unselected ones of the word lines WL, in response to the control of a control circuit. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

The sense amplifier 3 may be configured to sense, amplify, and output a difference in voltage between one of the bit lines BL, which is selected based on address information decoded by the column decoder 4, and a reference bit line.

The column decoder 4 may be configured to construct a data transmission path between the sense amplifier 3 and an external device (e.g., memory controller). The column decoder 4 may be configured to decode address information, which is input from the outside, and to select one of the bit lines BL, based on the decoded address information. The control logic 5 may generate control signals, which are used to control an operation of writing or reading data to or from the memory cell array 1.

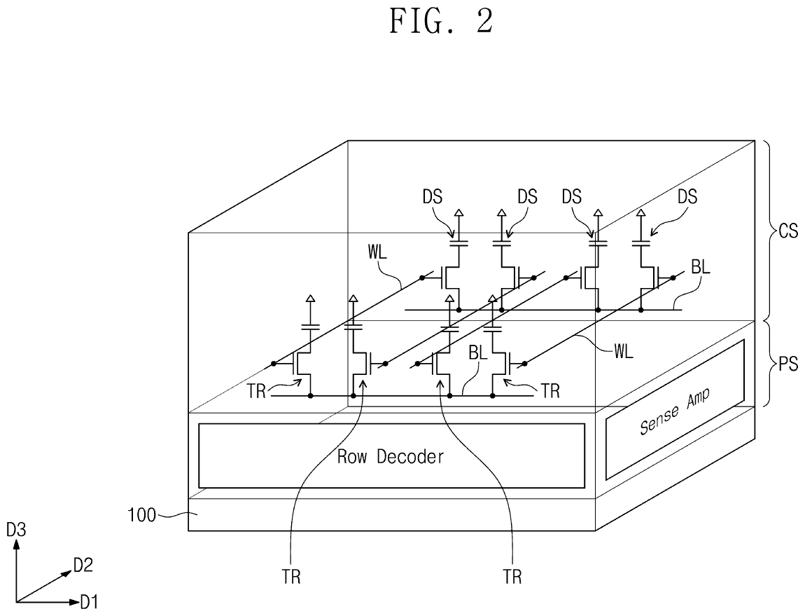

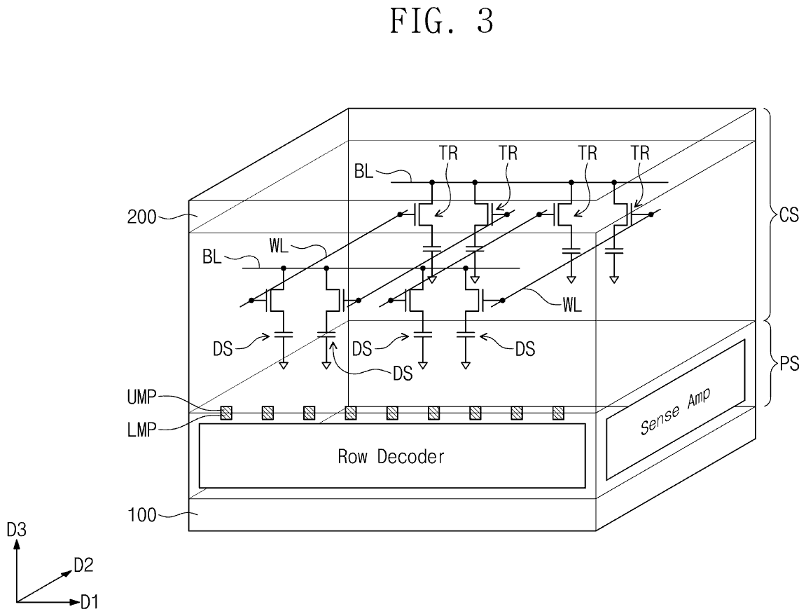

FIGS. 2 and 3 are perspective views, each of which schematically illustrates a semiconductor device according to an embodiment of the inventive concept.

Referring to FIGS. 2 and 3, the semiconductor device may include a peripheral circuit structure PS on a substrate 100 and a cell array structure CS (electrically) connected to the peripheral circuit structure PS. The substrate 100 may be a plate-shaped structure that is extended parallel to a plane defined by a first direction D1 and a second direction D2. The first and second directions D1 and D2 may be parallel to an upper surface (e.g., a top surface) of the substrate 100 and may not be parallel to each other. A third direction D3 may be perpendicular to the upper surface (e.g., the top surface) of the substrate 100 and may not be parallel to the first and second directions D1 and D2.

The peripheral circuit structure PS may include core and peripheral circuits that are formed on the substrate 100. The core and peripheral circuits may include the row and column decoders 2 and 4, the sense amplifier 3, and the control logics 5 described with reference to FIG. 1.

The cell array structure CS may include a memory cell array (e.g., 1 of FIG. 1), in which memory cells (e.g., MC of FIG. 1) are two-or three-dimensionally arranged. In an embodiment, the selection element TR of each of the memory cells MC of FIG. 1 may include a vertical channel transistor (VCT). The vertical channel transistor may include a channel pattern having a length direction in the third direction D3.

Referring to FIG. 2, the peripheral circuit structure PS may be provided on the substrate 100. The cell array structure CS may be provided on the peripheral circuit structure PS. Although not shown in the drawings, the peripheral circuit structure PS may be (electrically) connected to the cell array structure CS through an additional contact.

Referring to FIG. 3, the semiconductor device may have a chip-to-chip (C2C) structure. The peripheral circuit structure PS may be provided on the substrate 100. First metal pads LMP may be provided in an upper portion of the peripheral circuit structure PS. The first metal pads LMP may be (electrically) connected to the core and peripheral circuits. The first metal pads LMP in the peripheral circuit structure PS may be bonded to second metal pads UMP of the cell array structure CS, which will be described below. Thus, the peripheral circuit structure PS may be bonded to the cell array structure CS.

The cell array structure CS may be provided on a carrier substrate 200. The second metal pads UMP may be provided in a lower portion of the cell array structure CS. The second metal pads UMP may be (electrically) connected to the memory cell array 1 of FIG. 1.

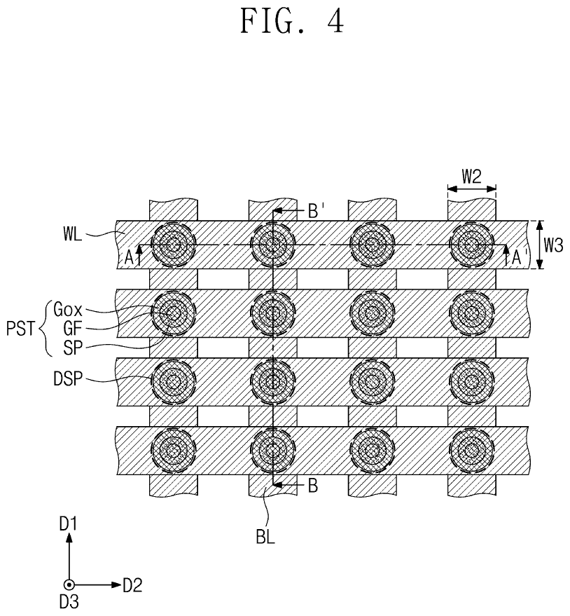

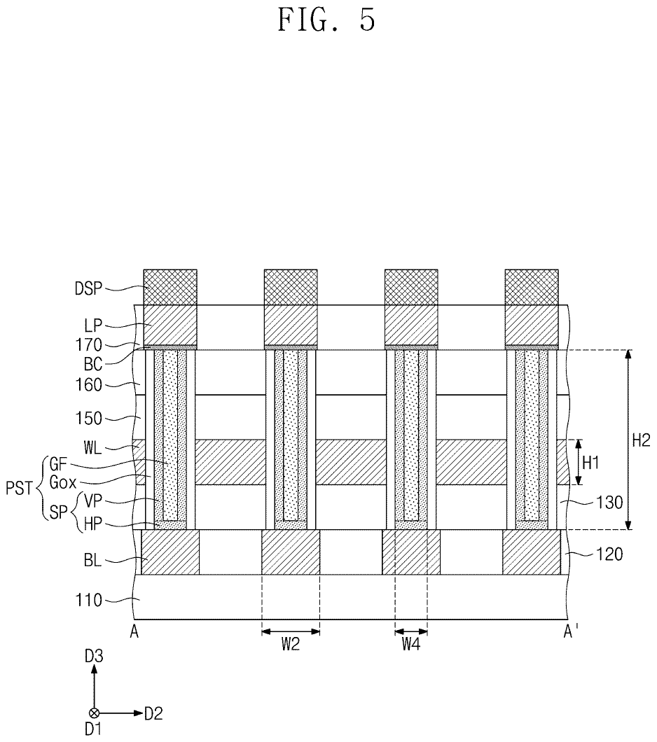

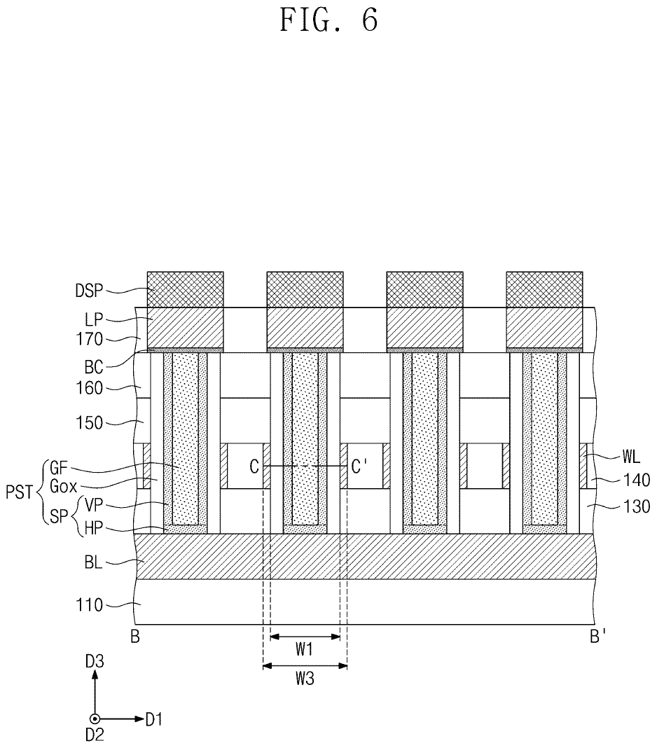

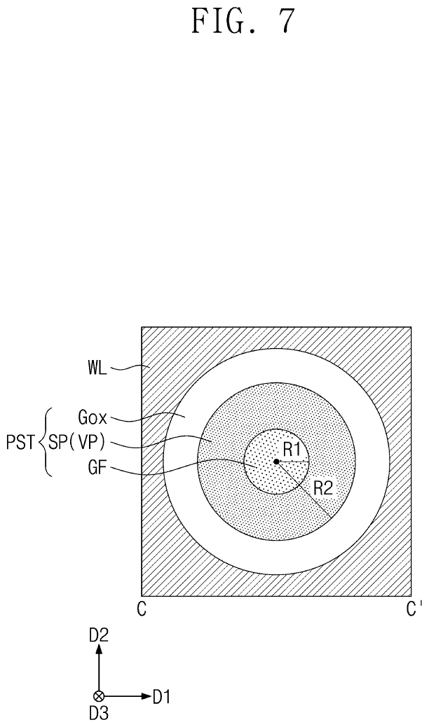

FIG. 4 is a plan view illustrating a semiconductor device according to an embodiment of the inventive concept. FIG. 5 is a sectional view, which is taken along a line A-A′ of FIG. 4 to illustrate a semiconductor device according to an embodiment of the inventive concept. FIG. 6 is a sectional view, which is taken along a line B-B′ of FIG. 4 to illustrate a semiconductor device according to an embodiment of the inventive concept. FIG. 7 is a plan view, which is taken along a line C-C′ of FIG. 6 to illustrate a semiconductor device according to an embodiment of the inventive concept.

FIGS. 4, 5, 6, and 7 are plan and sectional views illustrating elements in the cell array structure CS described with reference to FIGS. 2 and 3, according to an embodiment of the inventive concept.

The semiconductor device may include a first insulating layer 110. The first insulating layer 110 may include an insulating material.

Although not shown, the first insulating layer 110 may be provided below the cell array structure CS described with reference to FIG. 2. Here, the first insulating layer 110 may be adjacent to and in contact with the peripheral circuit structure PS described with reference to FIG. 2. Furthermore, the peripheral circuit structure PS described with reference to FIG. 2 may be interposed between the substrate 100 of FIG. 2 and the first insulating layer 110. In addition, the first insulating layer 110 may include interconnection lines, which are (electrically) connected to the core and peripheral circuits of the peripheral circuit structure PS described with reference to FIG. 2.

In an embodiment, since, although not shown, the cell array structure CS (e.g., of FIG. 2) of the semiconductor device is flipped or inverted, the first insulating layer 110 may be placed in an upper portion of the cell array structure CS described with reference to FIG. 3. Here, the first insulating layer 110 may be adjacent to and in contact with the carrier substrate 200 described with reference to FIG. 3. The semiconductor device is described with reference to the cell array structure CS (e.g., see FIG. 2) in a non-inverted state, but the inventive concept is not limited to this example.

The bit lines BL may be disposed on the first insulating layer 110. The bit lines BL may be extended in the first direction D1. The bit lines BL may be spaced apart from each other in the second direction D2.

In the present specification, the first direction D1 may be parallel to an upper surface (e.g., a top surface) of the first insulating layer 110, the second direction D2 may be parallel to the upper surface (e.g., the top surface) of the first insulating layer 110 and may not be parallel to the first direction D1, and the third direction D3 may be perpendicular to the upper surface (e.g., the top surface) of the first insulating layer 110.

The bit lines BL may include a conductive material. As an example, the bit lines BL may be formed of or include doped semiconductor materials (e.g., doped silicon and doped germanium), metallic materials (e.g., Ti, Mo, W, Cu, Al, Ta, Ru, Ir, and/or Co), metal silicide materials (e.g., silicide materials containing Ti, Mo, W, Cu, Al, Ta, Ru, Ir, and/or Co), and/or metal nitride materials (e.g., nitride materials containing Ti, Mo, W, Cu, Al, Ta, Ru, Ir, and/or Co). The bit lines BL may be provided to have a single-or multi-layered structure.

A second insulating layer 120 may be disposed between the bit lines BL. The second insulating layer 120 may be on the first insulating layer 110. The second insulating layer 120 may extend around the bit lines BL. The second insulating layer 120 may include an insulating material (e.g., silicon nitride).

A third insulating layer 130 may be disposed on the bit lines BL and the second insulating layer 120. The third insulating layer 130 may include an insulating material (e.g., silicon oxide).

The word lines WL may be disposed on the third insulating layer 130. The word lines WL may be extended in the second direction D2. The second direction D2 may be parallel to the upper surface (e.g., the top surface) of the first insulating layer 110. The word lines WL may be spaced apart from each other in the first direction D1. The word lines WL may include a conductive material. In an embodiment, the word lines WL may include a barrier metal layer and a metal layer. The word lines WL may be formed of or include, for example, metallic materials (e.g., Ti, Mo, W, Cu, Al, Ta, Ru, Ir, and/or Co), metal silicide materials (e.g., silicide materials containing Ti, Mo, W, Cu, Al, Ta, Ru, Ir, and/or Co), and/or metal nitride materials (e.g., nitride materials containing Ti, Mo, W, Cu, Al, Ta, Ru, Ir, and/or Co).

A fourth insulating layer 140 may be disposed between the word lines WL. The fourth insulating layer 140 may be on the third insulating layer 130. The fourth insulating layer 140 may extend around the word lines WL. The fourth insulating layer 140 may include an insulating material (e.g., silicon nitride).

A fifth insulating layer 150 and a sixth insulating layer 160 may be sequentially disposed on the word lines WL and the fourth insulating layer 140. The fifth insulating layer 150 may include insulating material (e.g., silicon oxide). The sixth insulating layer 160 may include an insulating material (e.g., silicon nitride) having an etch selectivity with respect to the fifth insulating layer 150.

Pillar structures PST may be provided at the intersections of the word lines WL and the bit lines BL, respectively. For example, the pillar structures PST may overlap the bit lines BL in the third direction D3. The pillar structures PST may be provided to extend into (e.g., extend through or penetrate) the word lines WL and may be disposed on each of the bit lines BL. The pillar structures PST may be provided to extend into (e.g., extend through or penetrate) the third, fifth, and sixth insulating layers 130, 150, and 160 in the third direction D3.

Each of the pillar structures PST may include a center insulating pattern GF, a semiconductor pattern SP, and a gate insulating pattern Gox.

The pillar structures PST may extend in the third direction D3, on each of the bit lines BL. The pillar structures PST on each of the bit lines BL may be spaced apart from each other in the first direction D1. The pillar structures PST may be provided to extend into (e.g., extend through or penetrate) the third, fifth, and sixth insulating layers 130, 150, and 160 and the word lines WL and may be (electrically) connected to the bit lines BL.

Each of the pillar structures PST may have a second length H2 in the third direction D3. Each of the pillar structures PST may have a first width W1 in the first direction D1. Each of the pillar structures PST may have the first width W1 in the second direction D2, but the inventive concept is not limited to this example. Unlike the illustrated structure, each of the pillar structures PST may have different widths in the first and second directions D1 and D2.

Each of the pillar structures PST may have a polygonal pillar shape or a circular pillar shape, but the inventive concept is not limited to this example.

Each of the pillar structures PST may have the first width W1 in the first direction D1, each of the bit lines BL may have a second width W2 in the second direction D2, each of the word lines WL may have a third width W3 in the first direction D1, and the semiconductor pattern SP may have a fourth width W4 in the second direction D2. Herein, a width of an element in a direction may mean a distance between opposite ends of the element in the direction.

The semiconductor patterns SP may be provided on each of the bit lines BL. The semiconductor pattern SP may include a horizontal portion HP and a vertical portion VP. The horizontal and vertical portions HP and VP may form the semiconductor pattern SP, which is provided in the form of a single object (e.g., an integrated structure or a monolithic structure).

The semiconductor pattern SP may include a semiconductor material. As an example, the semiconductor pattern SP may be formed of or include silicon (e.g., single crystalline silicon), germanium, and/or silicon-germanium. In an embodiment, the semiconductor pattern SP may include, for example, an oxide semiconductor material. Here, the oxide semiconductor material may include, for example, InGaZnO, InGaSiO, InSnZnO, InZnO, InGaO, ZnO, ZnSnO, ZnON, ZrZnSnO, SnO, HfInZnO, GaZnSnO, GaZnO, AlZnSnO, YbGaZnO, and/or InGaO, but the inventive concept is not limited to these examples. As an example, the semiconductor pattern SP may include oxygen (O) and two or more elements, which are selected from indium (In), gallium (Ga), tin (Sn), aluminum (AL), and zinc (Zn). As an example, the semiconductor pattern SP may include a two-dimensional semiconductor material. Here, the two-dimensional semiconductor material may include graphene, carbon nanotube, or combinations thereof.

The semiconductor pattern SP may have a hollow pillar shape extending in the third direction D3 (between corresponding vertical portions VP in the first direction D1 and the second direction D2). For example, the semiconductor pattern SP may be shaped like a hollow cylindrical pillar or a hollow polygonal pillar, but the inventive concept is not limited to this example. The vertical portion VP may be provided to extend into (e.g., extend through or penetrate) the third, fifth, and sixth insulating layers 130, 150, and 160 and the word lines WL and may be (electrically) connected to the horizontal portion HP. For example, the vertical portion VP may be shaped like a hollow cylinder or a hollow polygon, but the inventive concept is not limited to this example.

Referring to FIG. 7, the vertical portion VP may have a doughnut-shaped pattern with inner and outer radii of R1 and R2, respectively, when viewed in a plan view. The outer radius R2 of the vertical portion VP may be equal to the fourth width W4 in the second direction D2.

Referring back to FIGS. 4, 5, 6, and 7, the horizontal portion HP may be provided between each of the bit lines BL and the vertical portion VP. The horizontal portion HP may be in contact with a lower surface (e.g., a bottom surface) of the vertical portion VP. When viewed in a plan view, the horizontal portion HP may have a circular shape that has a radius equal to the outer radius R2. In other words, the horizontal portion HP may be overlapped with the vertical portion VP (in the third direction D3), and a side surface of the horizontal portion HP may be (substantially) coplanar with the outer side surface of the vertical portion VP.

The horizontal portion HP may have the fourth width W4 in the second direction D2, and each of the bit lines BL may have the second width W2 in the second direction D2. The fourth width W4 may be less (smaller) than the second width W2. In other words, the width of the horizontal portion HP in the second direction D2 may be less (smaller) than a width of a corresponding one of the bit lines BL in the second direction D2. That is, when viewed in a plan view, the semiconductor pattern SP, which includes the horizontal and vertical portions HP and VP, may be (at least partially) surrounded by the corresponding bit line BL, and the semiconductor pattern SP may be overlapped with the corresponding bit line BL (in the third direction D3).

In a cross-section taken parallel to the first and third directions D1 and D3, the semiconductor pattern SP may have a U-shaped structure provided as a single object (e.g., an integrated structure or a monolithic structure) including the horizontal and vertical portions HP and VP, and in a cross-section taken parallel to the second and third directions D2 and D3, the semiconductor pattern SP may have a U-shaped structure provided as a single object (e.g., an integrated structure or a monolithic structure) including the horizontal and vertical portions HP and VP.

The center insulating pattern GF may be provided on the horizontal portion HP. The center insulating pattern GF may be extended in the third direction D3. The center insulating pattern GF may be between the corresponding vertical portions VP in the first direction D1 and/or the second direction D2. The center insulating pattern GF may be in contact with a portion of an upper surface (e.g., a top surface) of the horizontal portion HP and an inner side surface of the vertical portion VP. That is, the center insulating pattern GF may (at least partially) fill an inner space of the semiconductor pattern SP (between the corresponding vertical portions VP in the first direction D1 and/or the second direction D2) having a hollow pillar shape. An upper surface (a top surface) of the center insulating pattern GF may be (substantially) coplanar with an upper surface (a top surface) of the vertical portion VP. A level of a lower surface (e.g., a bottom surface) of the center insulating pattern GF may be lower than a level of lower surfaces (e.g., bottom surfaces) of the word lines WL. Herein, the term “level”, “vertical level”, “height”, or the like may refer to a relative location with respect to a reference element in the third direction D3. A level, a vertical level, height, or the like may be a distance from the lower surface of the first insulating layer 110 in the third direction D3. For example, a higher level may mean a farther distance from the lower surface of the first insulating layer 110 in the third direction D3, and a lower level may mean a closer distance to the lower surface of the first insulating layer 110 in the third direction D3.

The center insulating pattern GF may have a pillar shape. In an embodiment, the center insulating pattern GF may be shaped like a circular pillar or a polygonal pillar, but the inventive concept is not limited to this example.

The center insulating pattern GF may include an insulating material. As an example, the center insulating pattern GF may be formed of or include silicon oxide.

Although not shown, bit line contacts (not shown) may be interposed between the horizontal portion HP and a corresponding one of the bit lines BL. Each of the bit line contacts (not shown) may (electrically) connect the semiconductor pattern SP to the corresponding bit line BL. The bit line contacts (not shown) may be formed of or include, for example, metallic materials and/or doped polysilicon. The bit line contacts (not shown) on each of the bit lines BL may be spaced apart from each other in the first direction D1.

The gate insulating pattern Gox may be provided to encompass (may be on or may extend around) an outer side surface of the semiconductor pattern SP. The gate insulating pattern Gox may be interposed between the word lines WL and the semiconductor pattern SP and may be extended along the semiconductor pattern SP and in the third direction D3. An upper surface (e.g., a top surface) of the gate insulating pattern Gox may be (substantially) coplanar with an upper surface (e.g., a top surface) of the semiconductor pattern SP and the upper surface (e.g., the top surface) of the center insulating pattern GF. The gate insulating pattern Gox may have a hollow pillar shape and may have a doughnut shape, when viewed in a plan view. In a plan view, for example, the center insulating pattern GF may be in the semiconductor pattern SP, and the semiconductor pattern SP may be in the gate insulating pattern Gox.

The gate insulating pattern Gox may include an insulating material. As an example, the gate insulating pattern Gox may be formed of or include silicon oxide and/or high-k dielectric materials. In the present specification, the high-k dielectric material may be defined as a material whose dielectric constant is greater (higher) than a dielectric constant of silicon oxide.

The word lines WL may be provided to encompass (may be on or may extend around) the pillar structures PST. That is, each of the pillar structures PST may be provided to extend into (e.g., extend through or penetrate) a corresponding one of the word lines WL and may be (electrically) connected to a corresponding one of the bit lines BL. The word lines WL may be disposed to encompass (may be on or may extend around) the semiconductor pattern SP, and thus, a transistor, which includes the semiconductor pattern SP, the word line WL corresponding thereto, and the gate insulating pattern Gox, may have the gate-all-around (GAA) structure. In a plan view, for example, the gate insulating pattern Gox may be in the word line WL.

The word lines WL may have the third width W3 in the first direction D1, and each of the pillar structures PST may have the first width W1 in the first direction D1. The third width W3 may be greater than the first width W1. In other words, the width of each of the word lines WL in the first direction D1 may be greater (larger) than the width of each of the pillar structures PST in the first direction D1, and thus, the word lines WL may have the gate-all-around (GAA) structure extending around (e.g., at least partially surrounding) the pillar structures PST.

Each of the word lines WL may have a first length H1 in the third direction D3, and each of the pillar structures PST may have a second length H2 in the third direction D3. The first length H1 may be less (smaller) than the second length H2. In other words, the length of each of the word lines WL in the third direction D3 may be less (smaller) than the length of each of the pillar structures PST in the third direction D3.

A storage node contact BC may be provided on each of the pillar structures PST. The storage node contact BC may be provided in a seventh insulating layer 170 and on each of the pillar structures PST. In an embodiment, the storage node contact BC may be in contact with the upper surfaces (e.g., the top surfaces) of the center insulating pattern GF, the vertical portion VP, and the gate insulating pattern Gox. The storage node contact BC may include a conductive material. As an example, the storage node contact BC may be formed of or include metallic materials and/or doped polysilicon. In an embodiment, a plurality of storage node contacts BC may be provided. The storage node contacts BC may be spaced apart from each other in the first and second directions D1 and D2 and may be overlapped with the pillar structures PST in the third direction D3, respectively.

A landing pad LP may be provided on the storage node contact BC. The landing pad LP may be (electrically) connected to the semiconductor pattern SP through the storage node contact BC. The landing pad LP may include a conductive material. As an example, the landing pad LP may be formed of or include doped semiconductor materials (e.g., doped silicon and doped germanium), metallic materials (e.g., Ti, Mo, W, Cu, Al, Ta, Ru, Ir, and/or Co), metal silicide materials (e.g., silicide materials containing Ti, Mo, W, Cu, Al, Ta, Ru, Ir, and/or Co), and/or metal nitride materials (e.g., nitride materials containing Ti, Mo, W, Cu, Al, Ta, Ru, Ir, and/or Co).

In an embodiment, a plurality of landing pads LP may be provided. The landing pads LP may be provided on the storage node contacts BC, respectively. The landing pads LP may be spaced apart from each other in the first and second directions D1 and D2 and may be overlapped with the pillar structures PST in the third direction D3, respectively. When viewed in a plan view, the landing pads LP may be arranged in a matrix shape. The landing pad LP may have various shapes (e.g., circular, elliptical, rectangular, square, rhombus, and hexagonal shapes), when viewed in a plan view.

The seventh insulating layer 170 may be provided to encompass (may be on or may extend around) the storage node contact BC and the landing pad LP. The seventh insulating layer 170 may be provided on the sixth insulating layer 160. The seventh insulating layer 170 may include an insulating material (e.g., silicon nitride). The seventh insulating layer 170 may be provided to have a single-or multi-layered structure. The seventh insulating layer 170 may be provided to (electrically) separate the storage node contacts BC from each other. The seventh insulating layer 170 may (electrically) separate the landing pads LP from each other.

A data storage pattern DSP may be provided on the landing pad LP. The data storage pattern DSP may be (electrically) connected to the semiconductor pattern SP through the landing pad LP and the storage node contact BC. In an embodiment, a plurality of data storage patterns DSP may be provided. The data storage patterns DSP may be spaced apart from each other in the first and second directions D1 and D2. The data storage pattern DSP may correspond to the data storage device DS described with reference to FIGS. 1 to 3.

In an embodiment, the data storage pattern DSP may be a capacitor including a lower electrode (e.g., a bottom electrode), a dielectric layer, and an upper electrode (e.g., a top electrode). In this case, the semiconductor device may be a dynamic random access memory (DRAM) device. In an embodiment, the data storage pattern DSP may include a magnetic tunnel junction pattern. In this case, the semiconductor device may be a magnetic random access memory (MRAM) device. In an embodiment, the data storage pattern DSP may be formed of or include a phase-change material or a variable resistance material. In this case, the semiconductor device may be a phase-change random access memory (PRAM) device or a resistive random access memory (ReRAM) device. However, the inventive concept is not limited to these examples, and the data storage pattern DSP may include various structures and/or materials which can be used to store data.

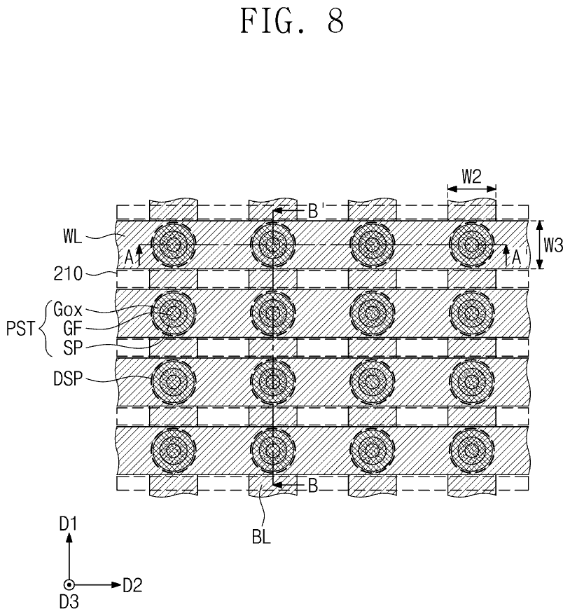

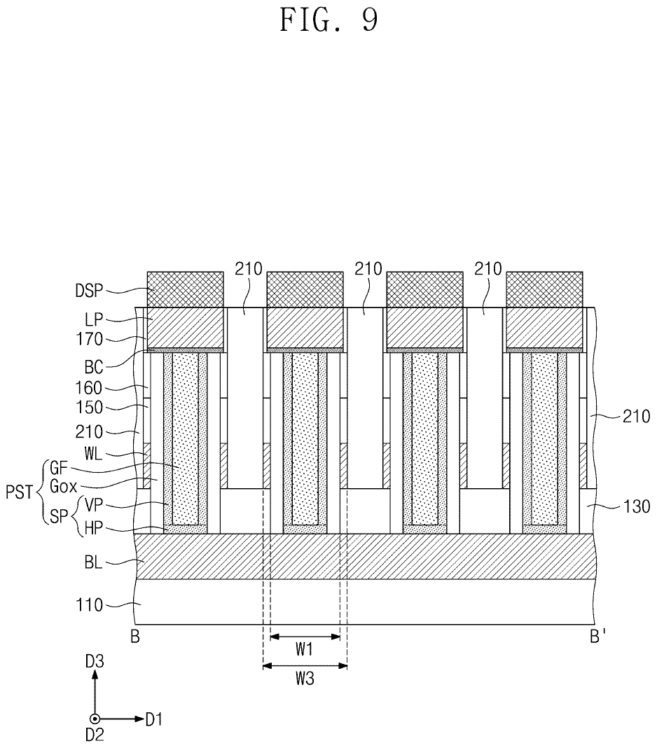

FIG. 8 is a plan view illustrating a semiconductor device according to an embodiment of the inventive concept. FIG. 9 is a sectional view, which is taken along a line B-B′ of FIG. 8 to illustrate a semiconductor device according to an embodiment of the inventive concept. However, the features different from the semiconductor devices according to the previous embodiments will be described in more detail below. For the sake of brevity, detailed descriptions of elements that are identical or similar to those previously described above may be omitted.

Referring to FIGS. 8 and 9, first isolation insulating layers 210 may be provided on the third insulating layer 130. The first isolation insulating layers 210 may be provided to extend into (e.g., extend through or penetrate) the fifth, sixth, and seventh insulating layers 150, 160, and 170. Each of the first isolation insulating layers 210 may be disposed between adjacent ones of the word lines WL. The first isolation insulating layers 210 may be provided on opposite side surfaces of each of the word lines WL (in the first direction D1) and may be extended along each of the word lines WL and in the second direction D2. The first isolation insulating layers 210 may have upper surfaces (e.g., top surfaces) that are (substantially) coplanar with an upper surface (e.g., a top surface) of the landing pad LP and an upper surface (e.g., a top surface) of the seventh insulating layer 170.

The first isolation insulating layers 210 may include an insulating material. As an example, the first isolation insulating layers 210 may be formed of or include silicon oxide, silicon nitride, and/or combinations thereof.

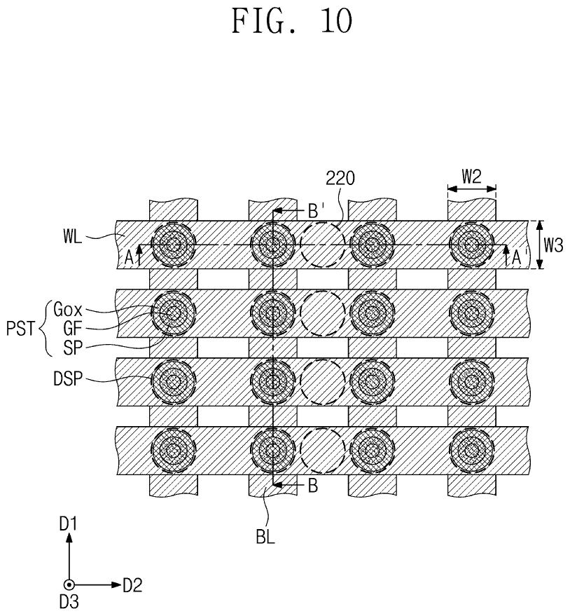

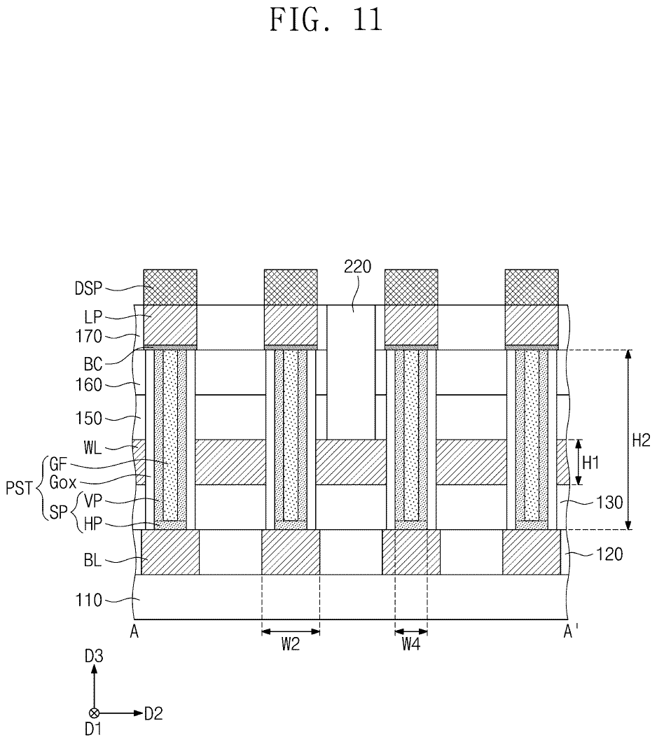

FIG. 10 is a plan view illustrating a semiconductor device according to an embodiment of the inventive concept. FIG. 11 is a sectional view, which is taken along a line A-A′ of FIG. 10 to illustrate a semiconductor device according to an embodiment of the inventive concept. However, the features different from the semiconductor devices according to the previous embodiments will be described in more detail below. For the sake of brevity, detailed descriptions of elements that are identical or similar to those previously described above may be omitted.

Referring to FIGS. 10 and 11, second isolation insulating layers 220 may be provided on the word lines WL, respectively, unlike the previous embodiment. The second isolation insulating layers 220 may be provided to extend into (e.g., extend through or penetrate) the fifth, sixth, and seventh insulating layers 150, 160, and 170 and may be in contact with the word lines WL. The second isolation insulating layers 220 may have upper surfaces (e.g., top surfaces) that are substantially coplanar with the upper surface (e.g., the top surface) of the landing pad LP and the upper surface (e.g., the top surface) of the seventh insulating layer 170.

Each of the second isolation insulating layers 220 may be disposed between the pillar structures PST, which are adjacent to each other in the second direction D2. Unlike the illustrated structure, the second isolation insulating layers 220 may be disposed between all pairs of the pillar structures PST adjacent to each other in the second direction D2.

Each of the second isolation insulating layers 220 may have a pillar shape. For example, the second isolation insulating layers 220 may have various shapes (e.g., circular, ellipse, and polygonal pillar shapes). When viewed in a plan view, the second isolation insulating layers 220 may have various shapes (e.g., circular, elliptical, rectangular, square, rhombic, and hexagonal shapes).

The second isolation insulating layers 220 may include an insulating material. As an example, the second isolation insulating layers 220 may be formed of or include silicon oxide, silicon nitride, and/or combinations thereof.

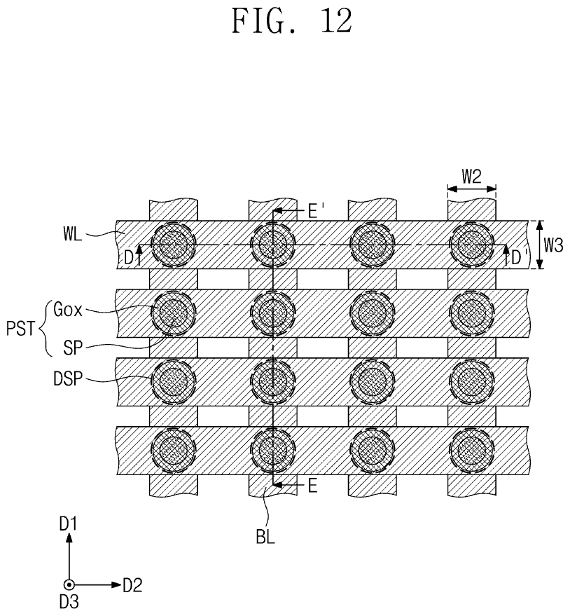

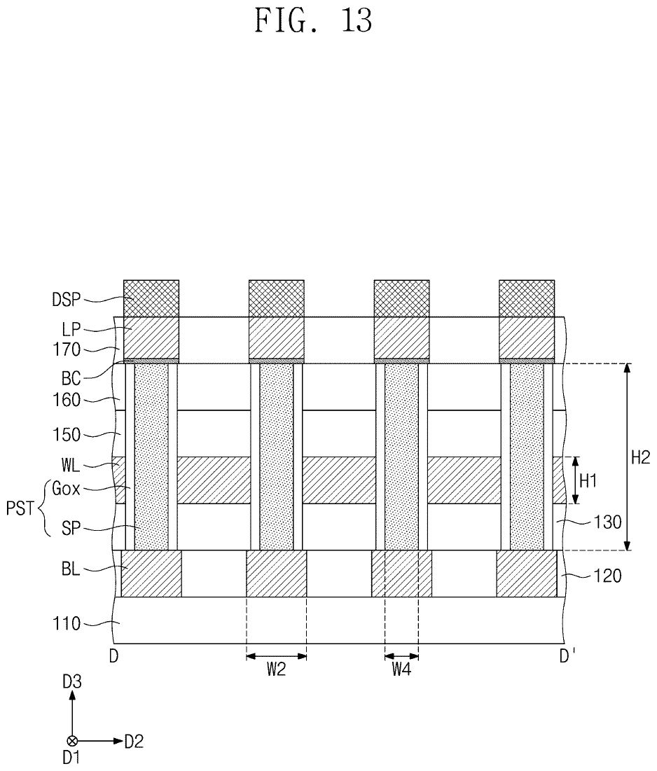

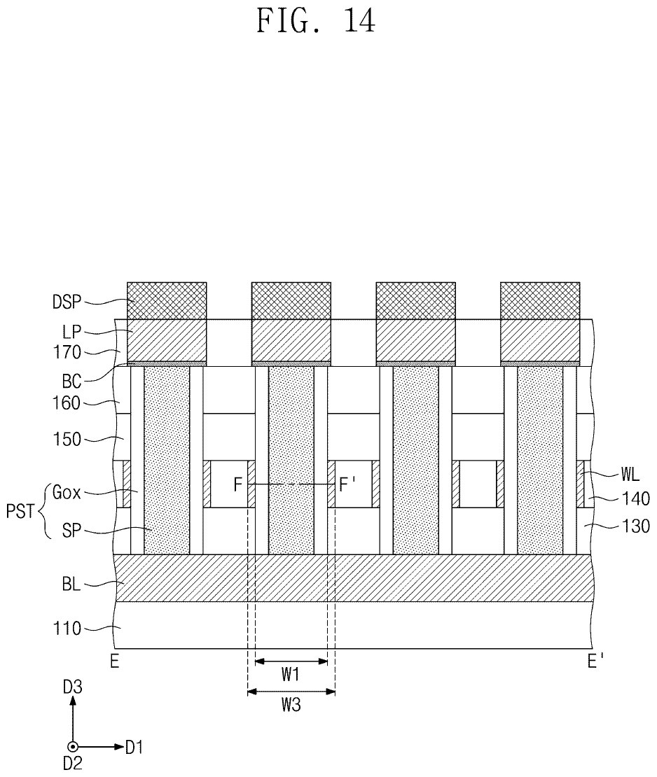

FIG. 12 is a plan view illustrating a semiconductor device according to an embodiment of the inventive concept. FIG. 13 is a sectional view, which is taken along a line D-D′ of FIG. 12 to illustrate a semiconductor device according to an embodiment of the inventive concept. FIG. 14 is a sectional view, which is taken along a line E-E′ of FIG. 12 to illustrate a semiconductor device according to an embodiment of the inventive concept. FIG. 15 is a plan view, which is taken along a line F-F′ of FIG. 14 to illustrate a semiconductor device according to an embodiment of the inventive concept. However, the features different from the semiconductor devices according to the previous embodiments will be described in more detail below. For the sake of brevity, detailed descriptions of elements that are identical or similar to those previously described above may be omitted.

Referring to FIGS. 12, 13, 14, and 15, each of the pillar structures PST may include the semiconductor pattern SP and the gate insulating pattern Gox. That is, the pillar structures PST may not include the center insulating pattern GF of FIG. 5, unlike the previous embodiment.

The semiconductor pattern SP may have a pillar shape, unlike the previous embodiment. In an embodiment, the semiconductor pattern SP may have various shapes (e.g., circular, ellipse, and polygonal pillar shapes).

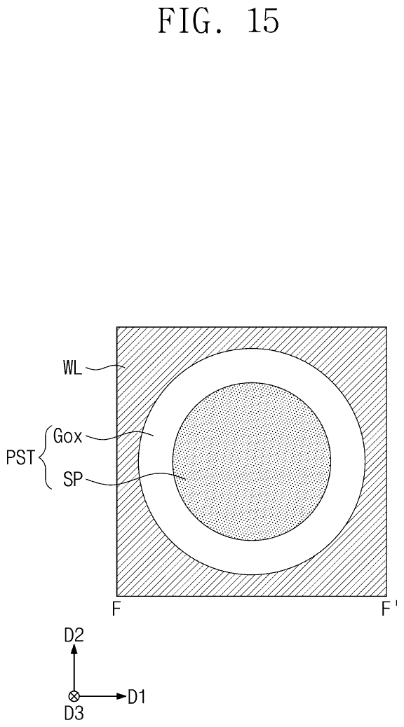

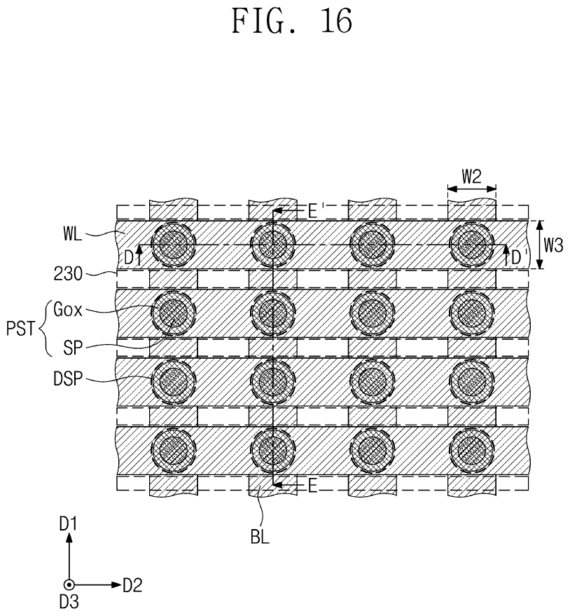

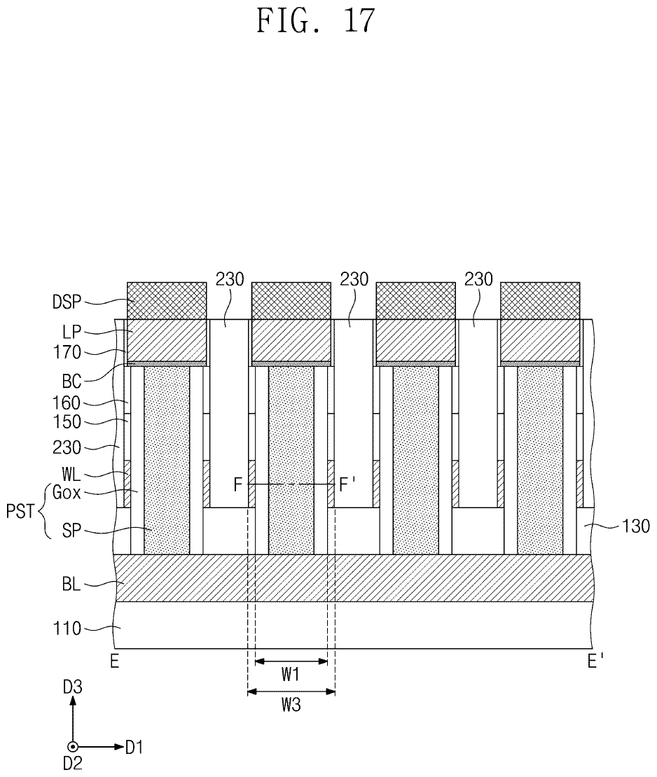

FIG. 16 is a plan view illustrating a semiconductor device according to an embodiment of the inventive concept. FIG. 17 is a sectional view, which is taken along a line E-E′ of FIG. 16 to illustrate a semiconductor device according to an embodiment of the inventive concept.

Referring to FIGS. 16 and 17, the pillar structure PST may include the semiconductor pattern SP and the gate insulating pattern Gox. The semiconductor pattern SP may have a pillar shape. That is, the pillar structures PST may not include the center insulating pattern GF of FIG. 5.

Third isolation insulating layers 230 may be provided on the third insulating layer 130. The third isolation insulating layers 230 may be provided to extend into (e.g., extend through or penetrate) the fifth, sixth, and seventh insulating layers 150, 160, and 170. The third isolation insulating layers 230 may be on opposite side surfaces of the word lines WL and extend along the word lines WL in the second direction D2. The third isolation insulating layers 230 may have upper surfaces (e.g., top surfaces) that are (substantially) coplanar with the upper surface (e.g., the top surface) of the landing pad LP and the upper surface (e.g., the top surface) of the seventh insulating layer 170.

The third isolation insulating layers 230 may include an insulating material. In an embodiment, the third isolation insulating layers 230 may be formed of or include silicon oxide, silicon nitride, and/or combinations thereof.

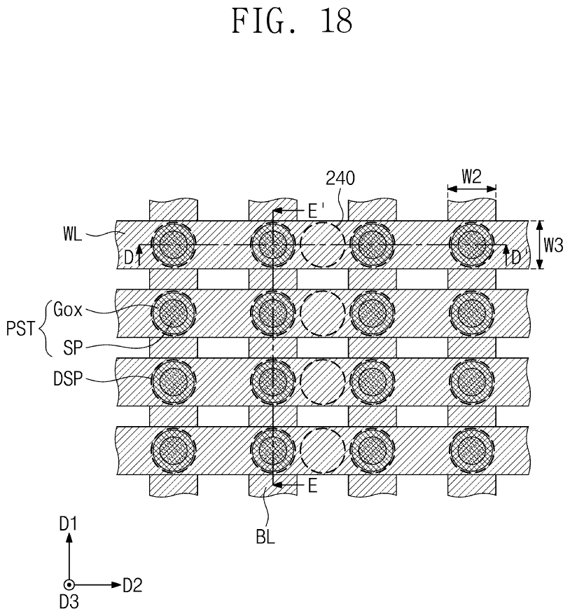

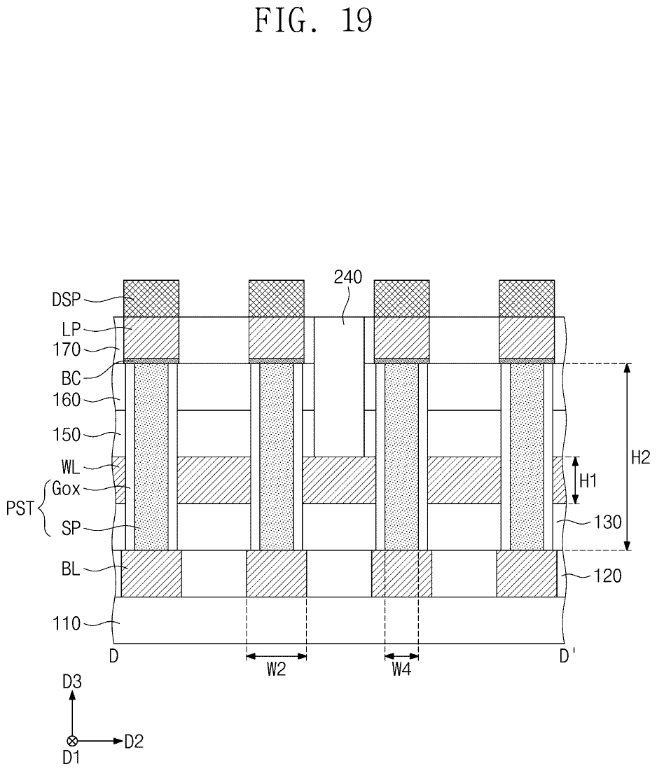

FIG. 18 is a plan view illustrating a semiconductor device according to an embodiment of the inventive concept. FIG. 19 is a sectional view, which is taken along a line D-D′ of FIG. 18 to illustrate a semiconductor device according to an embodiment of the inventive concept. However, the features different from the semiconductor devices according to the previous embodiments will be described in more detail below. For the sake of brevity, detailed descriptions of elements that are identical or similar to those previously described above may be omitted.

Referring to FIGS. 18 and 19, each of the pillar structures PST may include the semiconductor pattern SP and the gate insulating pattern Gox. The semiconductor pattern SP may have a pillar shape. That is, the pillar structures PST may not include the center insulating pattern GF of FIG. 5.

Fourth isolation insulating layers 240 may be provided to extend into (e.g., extend through or penetrate) the fifth, sixth, and seventh insulating layers 150, 160, and 170 and to be in contact with the word lines WL. Upper surfaces (e.g., top surfaces) of the fourth isolation insulating layers 240 may be (substantially) coplanar with the upper surface (e.g., the top surface) of the landing pad LP and the upper surface (e.g., the top surface) of the seventh insulating layer 170.

Each of the fourth isolation insulating layers 240 may be disposed between the pillar structures PST, which are adjacent to each other in the second direction D2. The fourth isolation insulating layers 240 may be disposed between all pairs of the pillar structures PST adjacent to each other in the second direction D2.

Each of the fourth isolation insulating layers 240 may have a pillar shape. As an example, the fourth isolation insulating layers 240 may have various shapes (e.g., circular, ellipse, and polygonal pillar shapes). When viewed in a plan view, the fourth isolation insulating layers 240 may have various shapes (e.g., circular, elliptical, rectangular, square, rhombic, and hexagonal shapes).

The fourth isolation insulating layers 240 may include an insulating material. As an example, the fourth isolation insulating layers 240 may be formed of or include silicon oxide, silicon nitride, and/or combinations thereof.

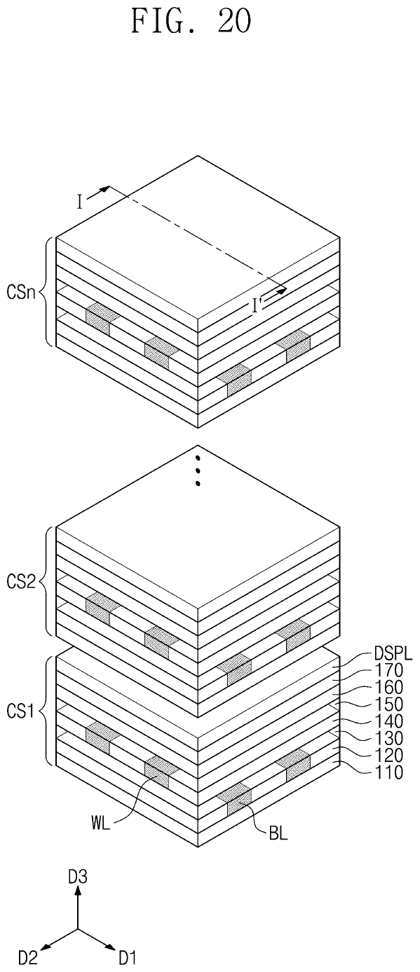

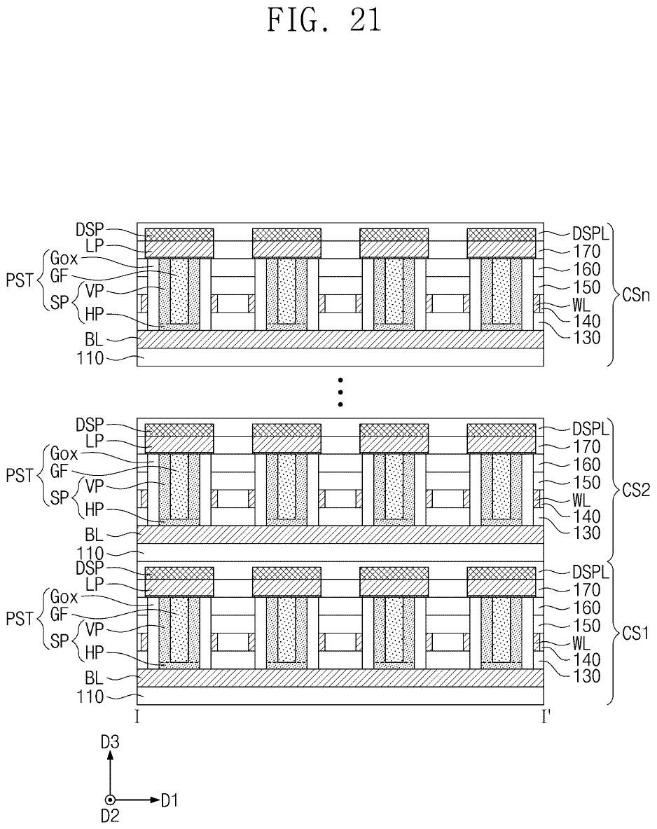

FIG. 20 is a perspective view illustrating a semiconductor device according to an embodiment of the inventive concept. FIG. 21 is a sectional view, which is taken along a line I-I′ of FIG. 20 to illustrate a semiconductor device according to an embodiment of the inventive concept. However, the features different from the semiconductor devices according to the previous embodiments will be described in more detail below. For the sake of brevity, detailed descriptions of elements that are identical or similar to those previously described above may be omitted.

Referring to FIGS. 20 and 21, first, second, . . . , and n-th cell array structures CS1, CS2, . . . , and CSn may be stacked in the third direction D3.

Each of the first, second, . . . , ands n-th cell array structures CS1, CS2, . . . , and CSn may include memory cells, which are two-dimensionally arranged in the first and second directions D1 and D2. Thus, the semiconductor device may include a three-dimensional memory cell array, in which memory cells are arranged in the first, second, and third directions D1, D2, and D3.

Each of the first, second, . . . , and n-th cell array structures CS1, CS2, . . . , and CSn may correspond to the cell array structure CS described with reference to FIGS. 2 and 3. In other words, each of the first, second, . . . , and n-th cell array structures CS1, CS2, . . . , and CSn may include the cell array structure according to the embodiment of FIGS. 4, 5, 6, and 7, may include the cell array structure according to the embodiment of FIGS. 8 and 9, may include the cell array structure according to the embodiment of FIGS. 10 and 11, may include the cell array structure according to the embodiment of FIGS. 12, 13, 14, and 15, may include the cell array structure according to the embodiment of FIGS. 16 and 17, or may include the cell array structure according to the embodiment of FIGS. 18 and 19.

In an embodiment, each of the first, second, . . . , and n-th cell array structures CS1, CS2, . . . , and CSn may further include a capping layer DSPL on (e.g., covering or overlapping) the data storage pattern DSP. The capping layer DSPL may include an insulating material.

The first insulating layer 110 of the second cell array structure CS2 may be disposed on the capping layer DSPL of the first cell array structure CS1, and adjacent ones of the first, second, . . . , and n-th cell array structures CS1, CS2, . . . , and CSn may also be provided to have this feature. In this case, the first, second, . . . , and n-th cell array structures CS1, CS2, . . . , and CSn may be sequentially stacked, and the semiconductor device including the first, second, . . . , and n-th cell array structures CS1, CS2, . . . , and CSn may be a three-dimensional semiconductor device.

The pillar structures PST are illustrated to have a long axis in the third direction D3, which is perpendicular to the upper surface (e.g., the top surface) of the first insulating layer 110, and the data storage pattern DSP is illustrated to be adjacent to the pillar structure PST in the third direction D3. However, the inventive concept is not limited to this example.

In an embodiment, the pillar structures PST may have a long axis in a horizontal direction (i.e., the first or second direction D1 or D2), which is parallel to the upper surface (e.g., the top surface) of the first insulating layer 110, and the data storage pattern DSP may be (electrically) connected to the pillar structure PST in the horizontal direction.

In an embodiment, unlike the illustrated structure, the data storage patterns DSP may be respectively provided between the pillar structures PST, which are adjacent to each other in a horizontal direction. The data storage pattern DSP may be extended in the third direction D3, and the data storage patterns DSP, which are included in two of the first, second, . . . , and n-th cell array structures CS1, CS2, . . . , and CSn adjacent to each other in the third direction D3, may be electrically connected to each other. In each of the first, second, . . . , and n-th cell array structures CS1, CS2, . . . , and CSn, the data storage pattern DSP may be overlapped with the pillar structures PST in the first or second direction D1 or D2.

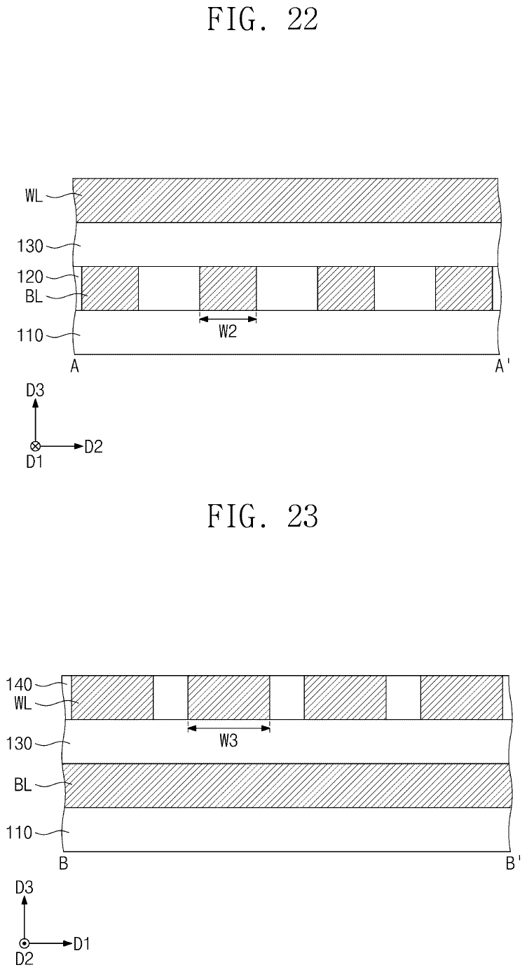

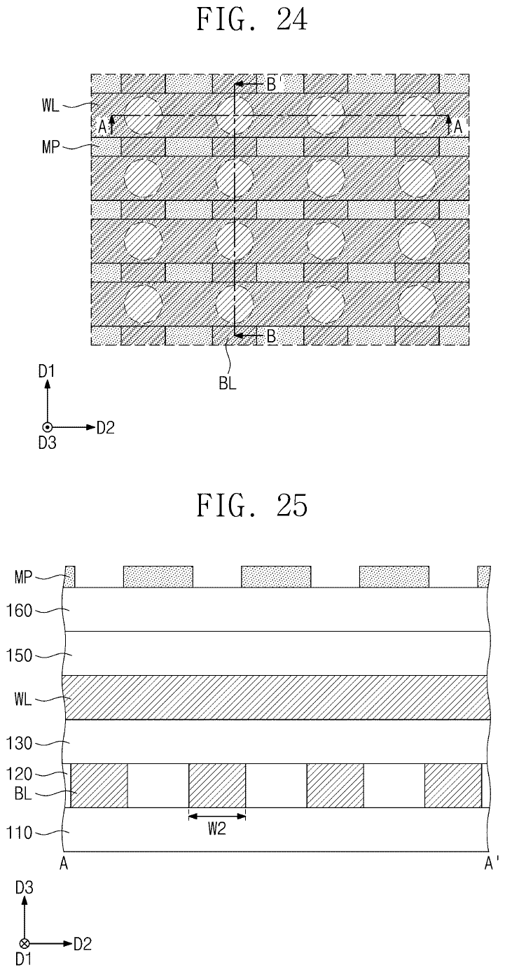

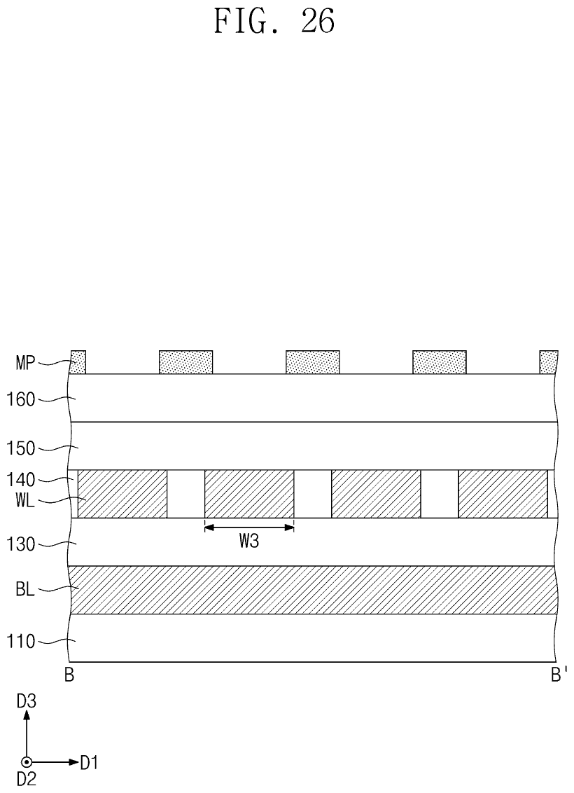

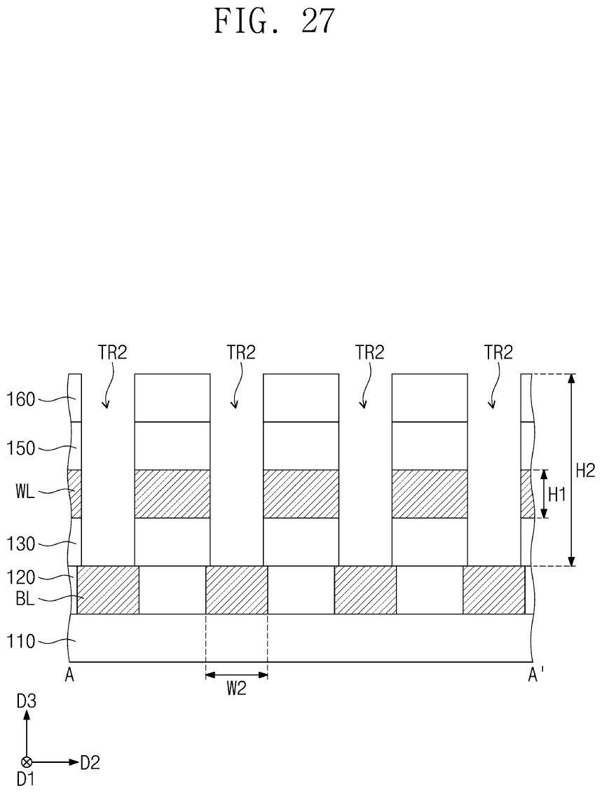

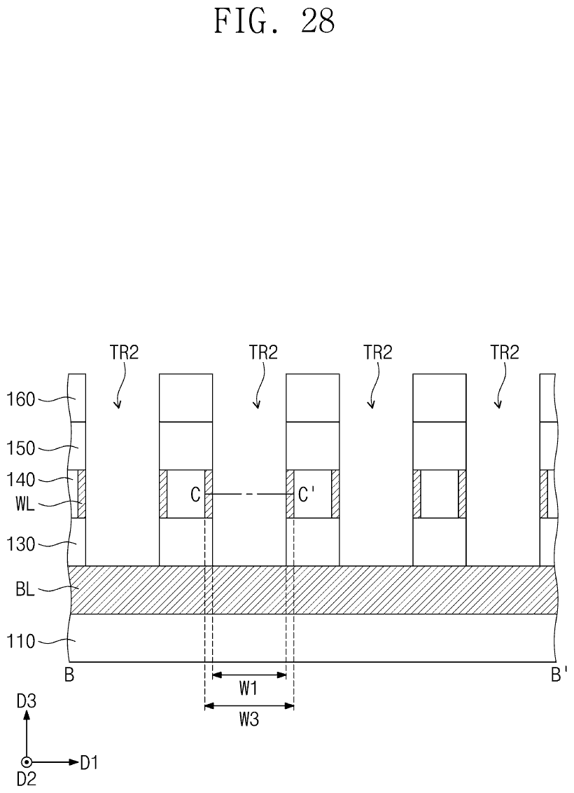

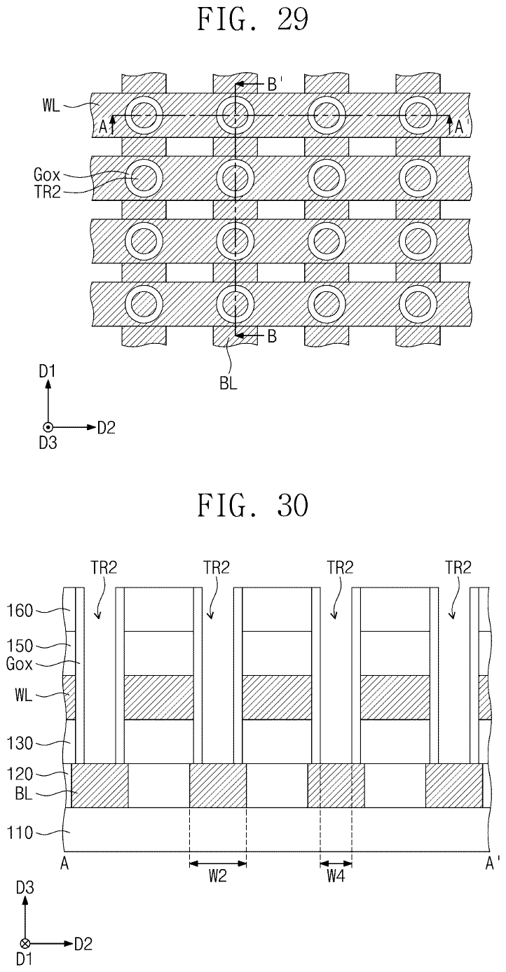

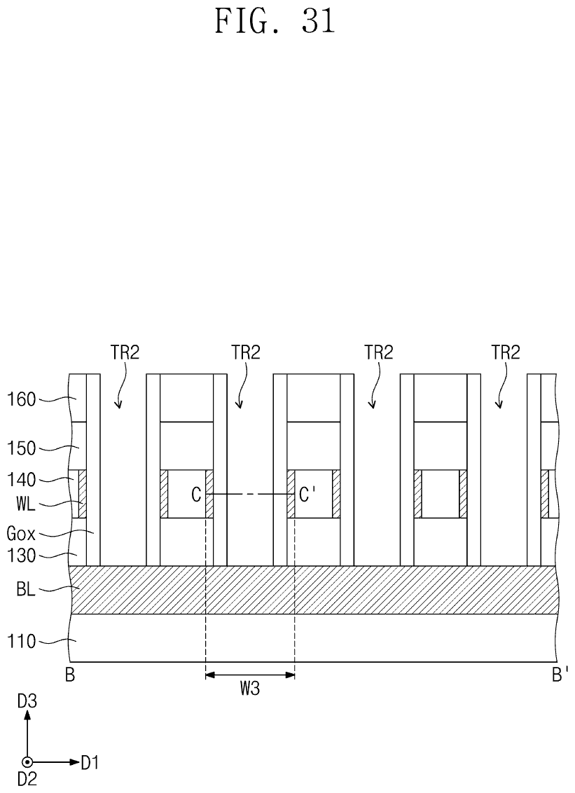

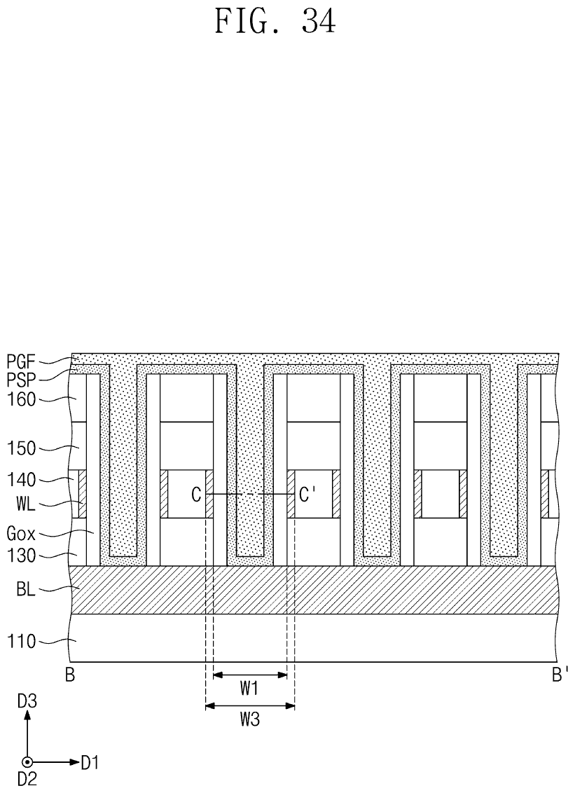

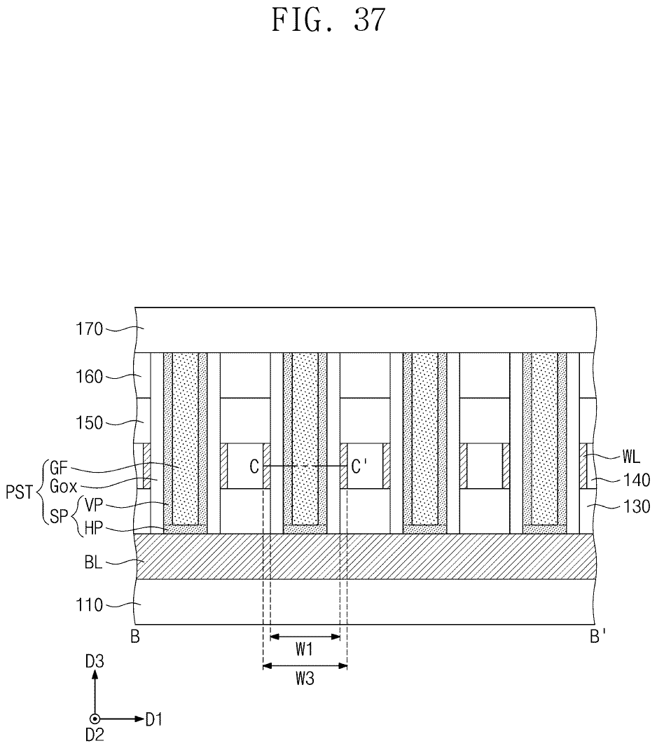

FIGS. 22 to 37 are diagrams illustrating a method of fabricating a semiconductor device, according to an embodiment of the inventive concept. More specifically, FIG. 22 is a sectional view corresponding to the line A-A′ of FIG. 4. FIG. 23 is a sectional view corresponding to the line B-B′ of FIG. 4. FIGS. 24, 29, 32, and 35 are plan views illustrating a semiconductor device according to an embodiment of the inventive concept. FIGS. 25 and 27 are sectional views corresponding to a line A-A′ of FIG. 24, and FIGS. 26 and 28 are sectional views corresponding to a line B-B′ of FIG. 24. FIGS. 30, 33, and 36 are sectional views corresponding to lines A-A′ of FIGS. 29, 32, and 35, respectively. FIGS. 31, 34, and 37 are sectional views corresponding to lines B-B′ of FIGS. 29, 32, and 35, respectively.

Referring to FIGS. 22 and 23, the substrate 100 of FIGS. 2 and 3 or an additional substrate (not shown) for the semiconductor device may be prepared. The first insulating layer 110 may be deposited on the substrate through a deposition process. In an embodiment, the first insulating layer 110 may be deposited by a physical vapor deposition (PVD) process, a chemical vapor deposition (CVD) process, and/or an atomic layer deposition (ALD) process.

After the deposition of the first insulating layer 110, the bit lines BL may be formed on the first insulating layer 110. Each of the bit lines BL may have the second width W2 in the second direction D2.

The formation of the bit lines BL may include depositing a bit line conductive layer (not shown) on the first insulating layer 110 and patterning the bit line conductive layer (not shown) to form the bit lines BL having the second width W2 in the second direction D2.

In an embodiment, the bit line conductive layer (not shown) may be deposited by a physical vapor deposition (PVD) process, a chemical vapor deposition (CVD) process, and/or an atomic layer deposition (ALD) process.

The bit line conductive layer (not shown) may include a conductive material. As an example, the bit line conductive layer (not shown) may be formed of or include doped semiconductor materials (e.g., doped silicon and doped germanium), metallic materials (e.g., Ti, Mo, W, Cu, Al, Ta, Ru, Ir, and/or Co), metal silicide materials (e.g., silicide materials containing Ti, Mo, W, Cu, Al, Ta, Ru, Ir, and/or Co), and/or metal nitride materials (e.g., nitride materials containing Ti, Mo, W, Cu, Al, Ta, Ru, Ir, and/or Co). The bit line conductive layer (not shown) may be formed to have a single-or multi-layered structure.

After the formation of the bit lines BL, the second insulating layer 120 may be formed between the bit lines BL. An upper surface (e.g., a top surface) of the second insulating layer 120 may be (substantially) coplanar with upper surfaces (e.g., top surfaces) of the bit lines BL. The formation of the second insulating layer 120 may include depositing an insulating material on the first insulating layer 110 and the bit lines BL to form a first dielectric layer (not shown) and removing a portion of the first dielectric layer (not shown) to expose the top surface of the bit lines BL.

In an embodiment, the first dielectric layer (not shown) may be deposited by a physical vapor deposition (PVD) process, a chemical vapor deposition (CVD) process, and/or an atomic layer deposition (ALD) process.

In an embodiment, a portion of the first dielectric layer (not shown) may be removed through a chemical mechanical polishing (CMP) process.

In an embodiment, the first dielectric layer (not shown) may be formed of or include silicon oxide and/or silicon nitride.

After the formation of the second insulating layer 120, the third insulating layer 130 may be formed on the second insulating layer 120. As an example, the third insulating layer 130 may include an insulating material (e.g., silicon oxide) having an etch selectivity with respect to the second insulating layer 120. As an example, the third insulating layer 130 may be deposited by a physical vapor deposition (PVD) process, a chemical vapor deposition (CVD) process, and/or an atomic layer deposition (ALD) process.

After the formation of the third insulating layer 130, the word lines WL may be formed on the third insulating layer 130. Each of the word lines WL may have the third width W3 in the first direction D1.

The formation of the word lines WL may include depositing a word line conductive layer (not shown) on the third insulating layer 130 and patterning the word line conductive layer (not shown) to form the word lines WL having the third width W3 in the first direction D1.

The word line conductive layer (not shown) may be deposited by a physical vapor deposition (PVD) process, a chemical vapor deposition (CVD) process, and/or an atomic layer deposition (ALD) process.

The word line conductive layer (not shown) may include a barrier metal layer and a metal layer. The word line conductive layer (not shown) may be formed of or include metallic materials (e.g., Ti, Mo, W, Cu, Al, Ta, Ru, Ir, and/or Co), metal silicide materials (e.g., silicide materials containing Ti, Mo, W, Cu, Al, Ta, Ru, Ir, and/or Co), and/or metal nitride materials (e.g., nitride materials containing Ti, Mo, W, Cu, Al, Ta, Ru, Ir, and/or Co).

After the formation of the word lines WL, the fourth insulating layer 140 may be formed between the word lines WL. The fourth insulating layer 140 may be formed to have an upper surface (e.g., a top surface) that is (substantially) coplanar with the upper surfaces (e.g., the top surfaces) of the word lines WL. The formation of the fourth insulating layer 140 may include depositing an insulating material on the third insulating layer 130 and the word lines WL to form a second dielectric layer (not shown) and removing a portion of the second dielectric layer (not shown) to expose the top surfaces of the word lines WL.

In an embodiment, the second dielectric layer (not shown) may be deposited by a physical vapor deposition (PVD) process, a chemical vapor deposition (CVD) process, and/or an atomic layer deposition (ALD) process.

In an embodiment, a portion of the second dielectric layer (not shown) may be removed through a chemical mechanical polishing (CMP) process.

In an embodiment, the second dielectric layer (not shown) and the fourth insulating layer 140 may include an insulating material (e.g., silicon nitride) having an etch selectivity with respect to the third insulating layer 130.

Referring to FIGS. 24, 25, and 26, after the formation of the fourth insulating layer 140, the fifth insulating layer 150 may be formed on the fourth insulating layer 140 and the word lines WL through a deposition process. As an example, the fifth insulating layer 150 may be deposited by a physical vapor deposition (PVD) process, a chemical vapor deposition (CVD) process, and/or an atomic layer deposition (ALD) process. As an example, the fifth insulating layer 150 may include an insulating material (e.g., silicon oxide) having an etch selectivity with respect to the fourth insulating layer 140.

After the formation of the fifth insulating layer 150, the sixth insulating layer 160 may be formed on the fifth insulating layer 150. The sixth insulating layer 160 may be deposited by a physical vapor deposition (PVD) process, a chemical vapor deposition (CVD) process, and/or an atomic layer deposition (ALD) process. The sixth insulating layer 160 may include an insulating material (e.g., silicon nitride) having an etch selectivity with respect to the fifth insulating layer 150.

After the formation of the sixth insulating layer 160, a mask pattern MP may be formed on the sixth insulating layer 160. At intersections of the bit and word lines BL and WL, the mask pattern MP may not cover the upper surface (e.g., the top surface) of the sixth insulating layer 160. The exposed portion of the upper surface (e.g., the top surface) of the sixth insulating layer 160 may have various shapes (e.g., circular, elliptical, and polygonal shapes).

The formation of the mask pattern MP may include coating the sixth insulating layer 160 with a photoresist material to form a mask layer (not shown) and performing exposing and developing processes to remove a portion of the mask layer (not shown). A remaining portion of the mask layer may form the mask pattern MP.

Referring to FIGS. 27 and 28, vertical holes TR2 may be formed by an etching process using the mask pattern MP as an etch mask. The vertical holes TR2 may be extended in the third direction D3 and may be spaced apart from each other in the first and second directions D1 and D2. Each of the vertical holes TR2 may have the first width W1 in the first direction D1.

The vertical holes TR2 may be formed to extend into (e.g., extend through or penetrate) the third, fifth, and sixth insulating layers 130, 150, and 160 and the word lines WL and to expose a portion of the upper surface (e.g., the top surface) of the bit lines BL to the outside. Side surfaces of the third, fifth, and sixth insulating layers 130, 150, and 160 may be exposed to the outside through the vertical holes TR2.

The formation of the vertical holes TR2 may include anisotropically and sequentially etching the sixth insulating layer 160, the fifth insulating layer 150, the word lines WL, and the third insulating layer 130 using the mask pattern MP as an etch mask. In other words, the sixth insulating layer 160, the fifth insulating layer 150, the word lines WL, and the third insulating layer 130 may be sequentially etched using the mask pattern MP.

The bit lines BL may include a material having an etch selectivity with respect to the third insulating layer 130, and in this case, they may be used as an etch stopper in the process of anisotropically etching the third insulating layer 130.

After the formation of the vertical holes TR2, the mask pattern MP may be removed. For example, the removal of the mask pattern MP may be performed through an ashing or strip process.

Referring to FIGS. 29, 30, and 31, after the removal of the mask pattern MP, the gate insulating pattern Gox may be formed on (to cover or overlap) inner side surfaces of the vertical holes TR2. The gate insulating pattern Gox may be on (e.g., cover or overlap) a portion of the upper surface (e.g., the top surface) of the bit lines BL.

The formation of the gate insulating pattern Gox may include depositing a gate insulating layer (not shown) to cover the inner side surfaces of the vertical holes TR2 and the top surface of the sixth insulating layer 160 with a (substantially) uniform thickness and performing an etch-back process to partially remove the gate insulating layer (not shown) on the upper surface (e.g., the top surface) of the sixth insulating layer 160 and the upper surfaces (e.g., the top surfaces) of the bit lines BL. The upper surface (e.g., the top surface) of the sixth insulating layer 160 and portions of the upper surfaces (e.g., the top surfaces) of the bit lines BL may be exposed to the outside through the etch-back process, and the gate insulating layer (not shown) may be divided into plurality of gate insulating patterns Gox.

As an example, the gate insulating layer (not shown) may be deposited by a physical vapor deposition (PVD) process, a chemical vapor deposition (CVD) process, and/or an atomic layer deposition (ALD) process.

The gate insulating layer (not shown) may include an insulating material. As an example, the gate insulating layer (not shown) may be formed of or include silicon oxide and/or high-k dielectric materials.

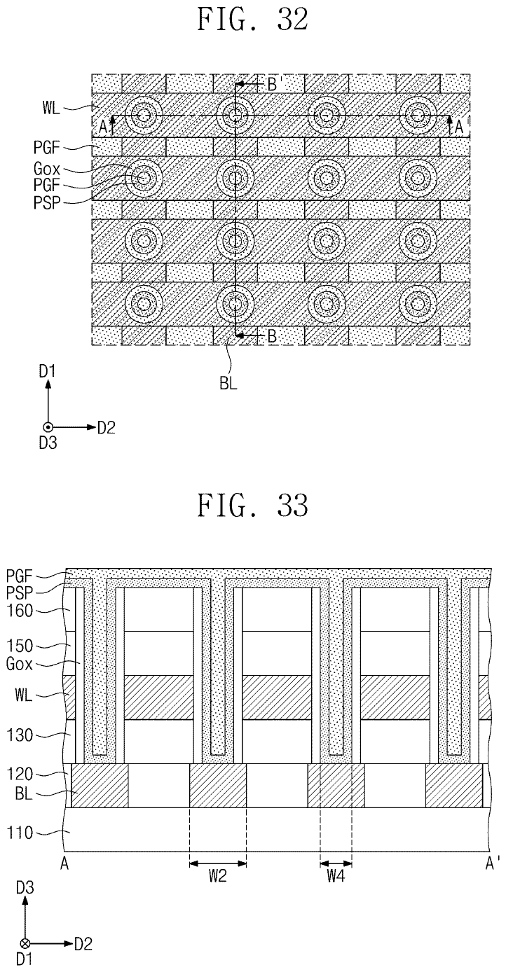

Referring to FIGS. 32, 33, and 34, after the formation of the gate insulating pattern Gox, a semiconductor layer PSP may be formed to be on (e.g., cover or overlap) the upper surface (e.g., the top surface) of the bit lines BL, the gate insulating pattern Gox, and the upper surface (e.g., the top surface) of the sixth insulating layer 160, which are exposed to the outside. The semiconductor layer PSP may be formed to have a (substantially) uniform thickness. By forming the semiconductor layer PSP, a gap region, which is encompassed (e.g., at least partially surrounded) by the semiconductor layer PSP, may be defined in each vertical hole TR2.

The semiconductor layer PSP may be formed through a deposition process. As an example, the semiconductor layer PSP may be deposited by a physical vapor deposition (PVD) process, a chemical vapor deposition (CVD) process, and/or an atomic layer deposition (ALD) process.

The semiconductor layer PSP may include a semiconductor material. As an example, the semiconductor layer PSP may be formed of or include silicon (e.g., single crystalline silicon), germanium, and/or silicon-germanium. In an embodiment, the semiconductor layer PSP may include an oxide semiconductor material. Here, the oxide semiconductor material may include, for example, InGaZnO, InGaSiO, InSnZnO, InZnO, InGaO, ZnO, ZnSnO, ZnON, ZrZnSnO, SnO, HfInZnO, GaZnSnO, GaZnO, AlZnSnO, YbGaZnO, and/or InGaO, but the inventive concept is not limited to these examples. As an example, the semiconductor layer PSP may include a two-dimensional semiconductor material. Here, the two-dimensional semiconductor material may include graphene, carbon nanotube, and/or combinations thereof.

Since the semiconductor layer PSP is formed after the formation of the gate insulating pattern Gox, it may reduce (e.g., prevent) hydrogen atoms, which are produced in the deposition process of the gate insulating pattern Gox, from entering the semiconductor layer PSP.

After the formation of the semiconductor layer PSP, a gapfill insulating layer PGF may be formed to (at least partially) fill the vertical holes TR2 provided with the semiconductor layer PSP. The gapfill insulating layer PGF may be (at least partially) surrounded by the semiconductor layer PSP.

The gapfill insulating layer PGF may be formed through a deposition process. As an example, the gapfill insulating layer PGF may be deposited by a physical vapor deposition (PVD) process, a chemical vapor deposition (CVD) process, and/or an atomic layer deposition (ALD) process.

Since the gapfill insulating layer PGF is immediately deposited after the deposition of the semiconductor layer PSP, it may reduce (e.g., prevent) the exposure of the semiconductor layer PSP to hydrogen gas in a subsequent deposition process. Thus, it may reduce (e.g., prevent) the deterioration of the device caused by hydrogen entering the semiconductor layer PSP and improve the reliability and electrical characteristics of the semiconductor device.

In some embodiments, the semiconductor layer PSP may be formed to fully fill the vertical holes TR2 provided with the gate insulating pattern Gox.

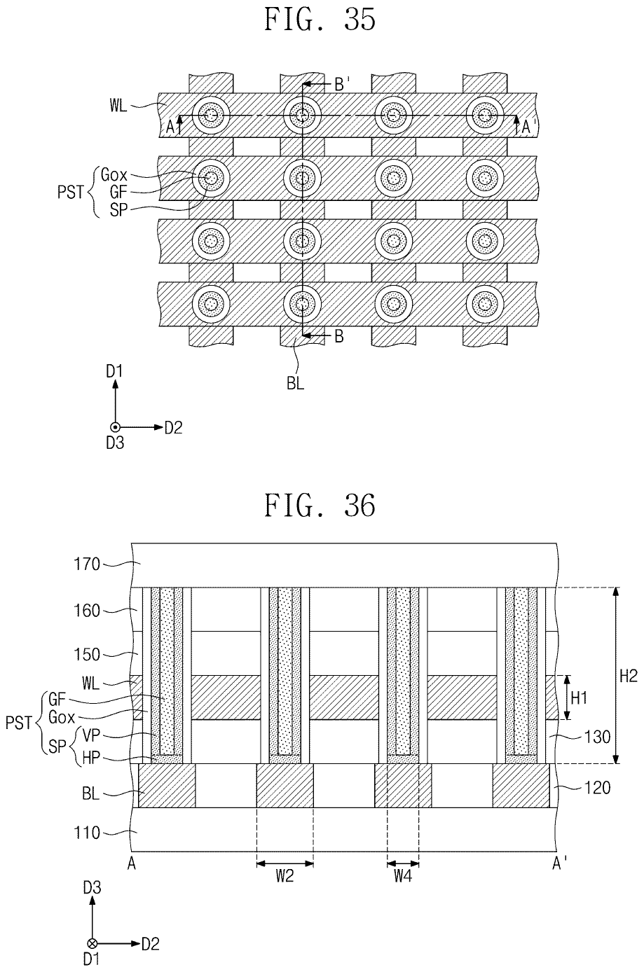

Referring to FIGS. 35, 36, and 37, after the formation of the gapfill insulating layer PGF, the center insulating pattern GF and the semiconductor pattern SP may be formed by partially removing the gapfill insulating layer PGF and the semiconductor layer PSP. A remaining portion of the gapfill insulating layer PGF may form the center insulating pattern GF, and a remaining portion of the semiconductor layer PSP may form the semiconductor pattern SP. In detail, a planarization process may be performed on the gapfill insulating layer PGF and the semiconductor layer PSP to expose the upper surface (e.g., the top surface) of the sixth insulating layer 160. As an example, the gapfill insulating layer PGF and the semiconductor layer PSP may be removed through a chemical mechanical polishing (CMP) process.

The gate insulating pattern Gox, the center insulating pattern GF, and the semiconductor pattern SP may constitute each of the pillar structures PST.

After the formation of the center insulating pattern GF and the semiconductor pattern SP, an oxygen annealing process or an oxygen curing process may be performed. The oxygen annealing process may be performed to compensate for the oxygen deficiency in the semiconductor pattern SP and to increase the charge mobility in the semiconductor pattern SP, and furthermore, since the defects or damages in the gate insulating pattern Gox are cured, the quality of the gate insulating pattern Gox may be improved.

The oxygen annealing process may be performed through the upper surface (e.g., the top surface) of the semiconductor pattern SP.

Since the center insulating pattern GF containing an oxide material is disposed to be in contact with the semiconductor pattern SP, the efficiency in the oxygen annealing process on the semiconductor pattern SP may be improved, compared to the case that the center insulating pattern GF is absent. Thus, the time required for the oxygen annealing process may be reduced. Since the time required for the oxygen annealing process is reduced, an amount of metal oxide, which is formed between the bit lines BL and the semiconductor patterns SP in the oxygen annealing process, may be reduced. In this case, a contact resistance between the bit lines BL and the semiconductor patterns SP may be lowered, and thus, the reliability and electrical characteristics of the semiconductor device may be improved.

After the oxygen annealing process, the seventh insulating layer 170 may be formed on the pillar structures PST and the sixth insulating layer 160. The seventh insulating layer 170 may be formed through a deposition process. As an example, the seventh insulating layer 170 may be deposited by a physical vapor deposition (PVD) process, a chemical vapor deposition (CVD) process, and/or an atomic layer deposition (ALD) process.

Referring to FIGS. 4, 5, 6, and 7, after the oxygen annealing process, the storage node contact BC may be formed in the seventh insulating layer 170. The formation of the storage node contact BC may include patterning the seventh insulating layer 170 to form an opening (not shown) and forming the storage node contact BC on the pillar structures PST and the sixth insulating layer 160, which are exposed by the opening (not shown), through a deposition process.

After the formation of the storage node contact BC, the landing pad LP may be formed to (at least partially) fill the opening. The formation of the landing pad LP may include depositing a landing pad layer (not shown) on the opening and the seventh insulating layer 170 and removing a portion of the landing pad layer to form the landing pad LP as a remaining portion of the landing pad layer. The upper surface (e.g., the top surface) of the landing pad LP may be (substantially) coplanar with the upper surface (e.g., the top surface) of the seventh insulating layer 170.

The landing pad layer (not shown) may be deposited by a physical vapor deposition (PVD) process, a chemical vapor deposition (CVD) process, and/or an atomic layer deposition (ALD) process. As an example, a portion of the landing pad layer (not shown) may be removed through a chemical mechanical polishing (CMP) process.

After the formation of the landing pad LP, the data storage pattern DSP may be formed on the landing pad LP.

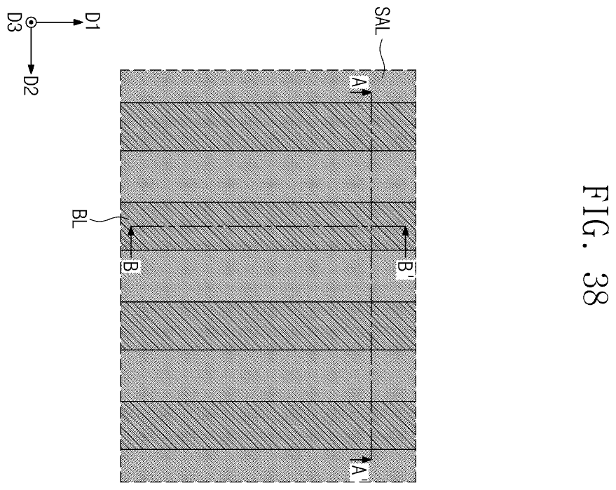

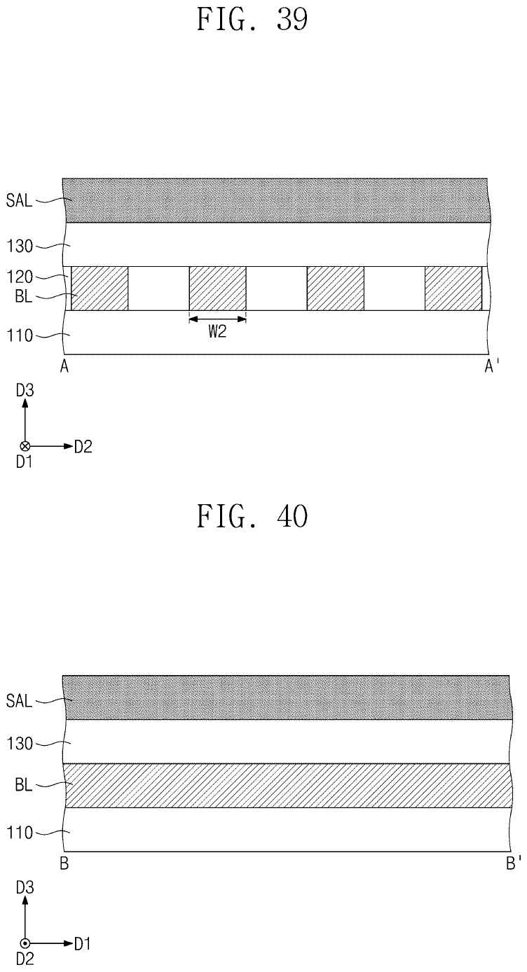

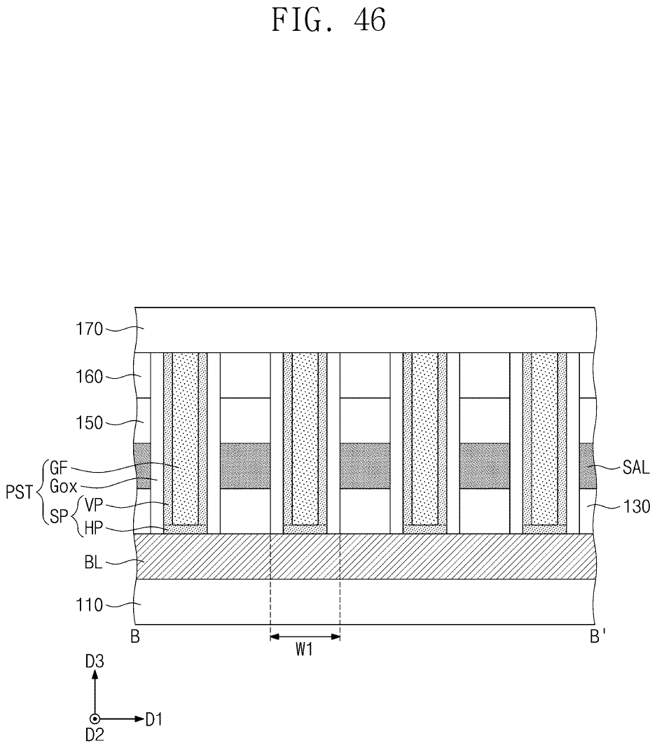

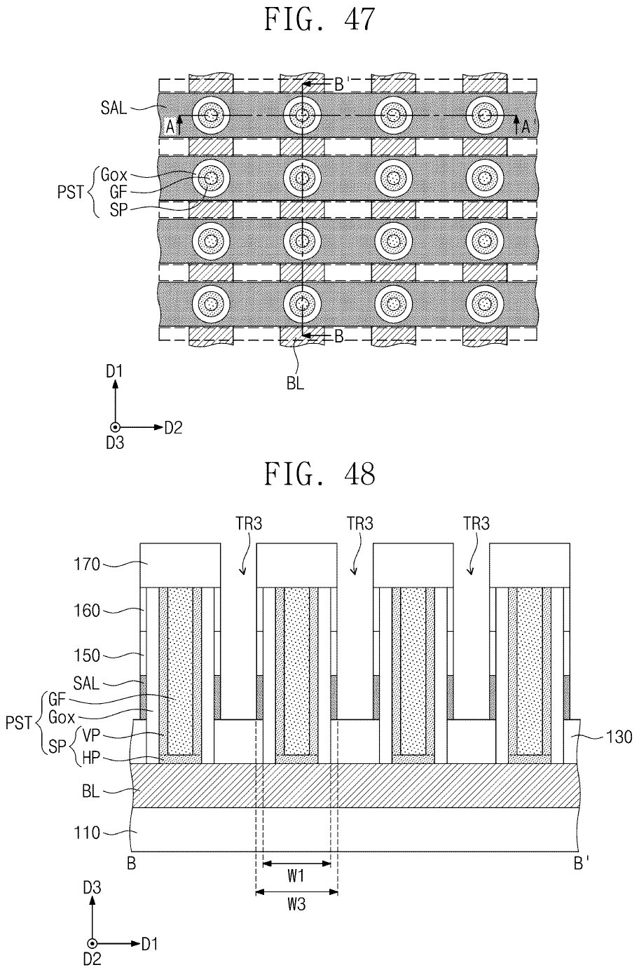

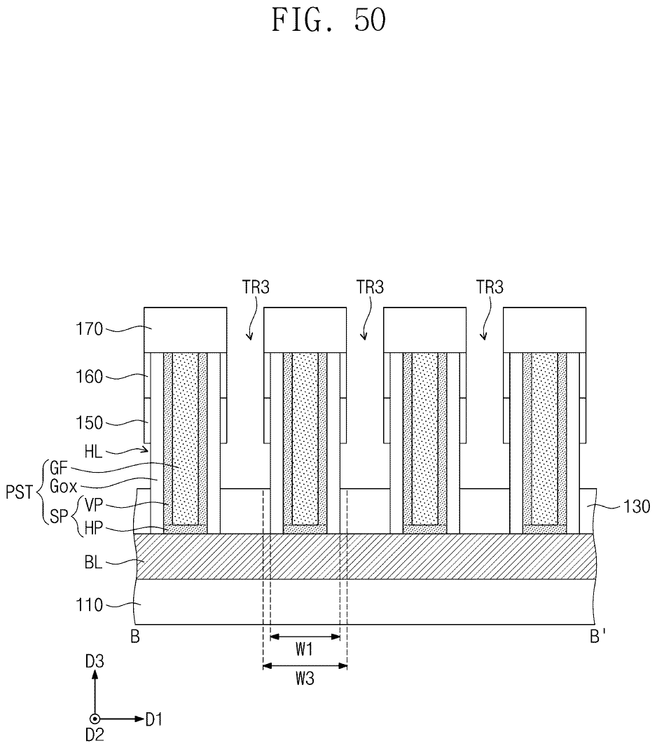

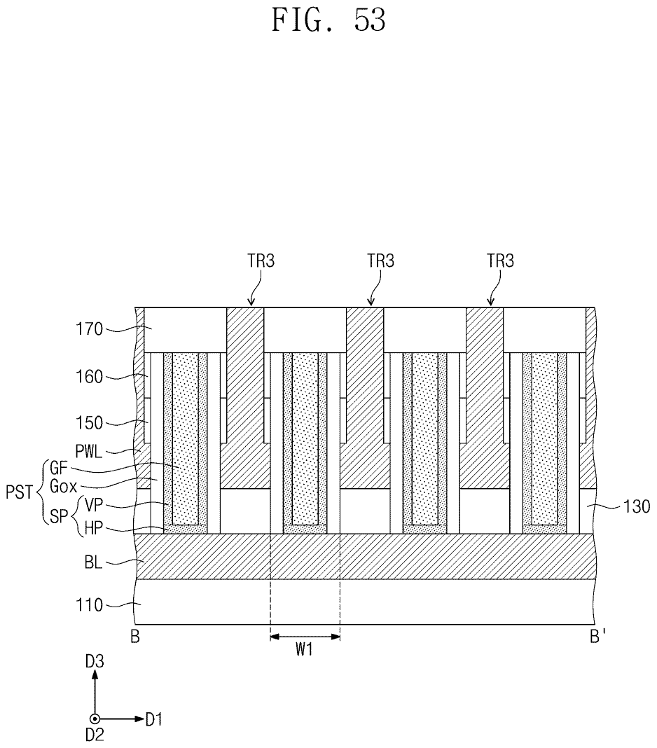

FIGS. 38 to 55 are diagrams illustrating a method of fabricating a semiconductor device, according to an embodiment of the inventive concept. More specifically, FIGS. 38, 41, 44, 47, 51, and 54 are plan views illustrating a semiconductor device according to an embodiment of the inventive concept. FIGS. 39, 42, 45, 49, and 52 are sectional views corresponding to lines A-A′ of FIGS. 38, 41, 44, 47, and 51, respectively. FIGS. 40, 43, 46, 53, and 55 are sectional views corresponding to lines B-B′ of FIGS. 38, 41, 44, 51, and 54, respectively. FIGS. 48 and 50 are sectional views corresponding to a line B-B′ of FIG. 47.

Processes to be performed after forming the third insulating layer 130 of FIGS. 22 and 23 will be described below. The processes of FIGS. 22 and 23 may be performed in advance.

Referring to FIGS. 38, 39, and 40, after the formation of the third insulating layer 130, a sacrificial layer SAL may be formed on the third insulating layer 130. The sacrificial layer SAL may include a material having an etch selectivity with respect to the third insulating layer 130. As an example, the sacrificial layer SAL may be formed of or include silicon nitride.

Referring to FIGS. 41, 42, and 43, after the formation of the sacrificial layer SAL, the fifth insulating layer 150 and the sixth insulating layer 160 may be sequentially stacked on the sacrificial layer SAL.

After the sequential stacking of the fifth and sixth insulating layers 150 and 160, the vertical holes TR2 may be formed to extend into (e.g., extend through or penetrate) the third, fifth, and sixth insulating layers 130, 150, and 160 and the sacrificial layer SAL. The vertical holes TR2 may be formed to expose portions of upper surfaces (e.g., top surfaces) of the bit lines BL to the outside.

After the formation of the vertical holes TR2, the gate insulating patterns Gox may be formed on inner side surfaces of the vertical holes TR2.

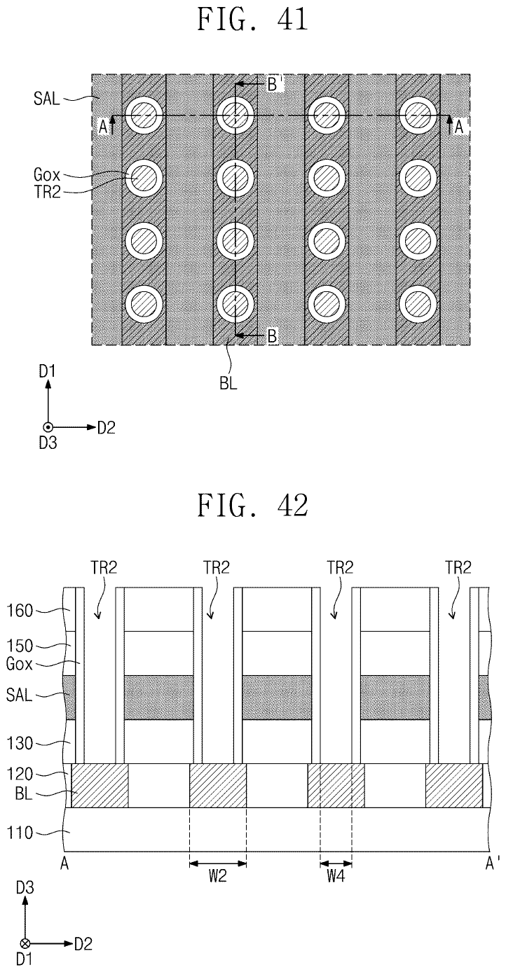

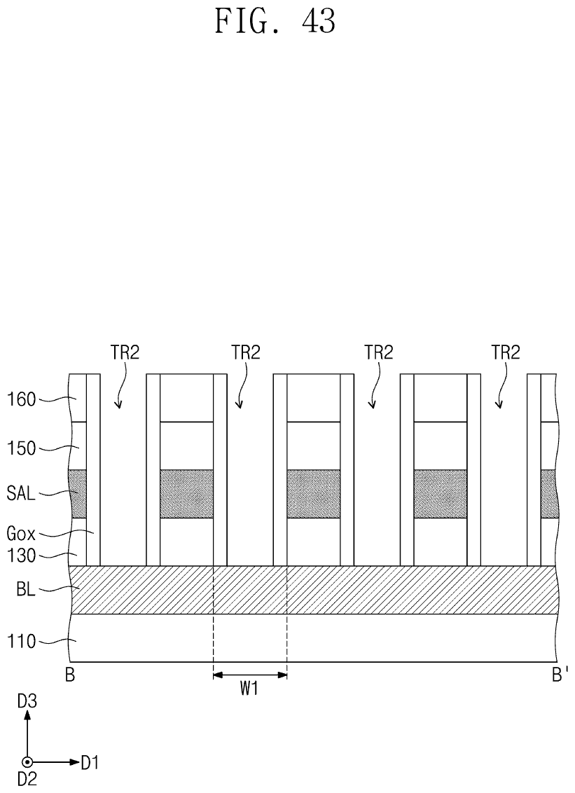

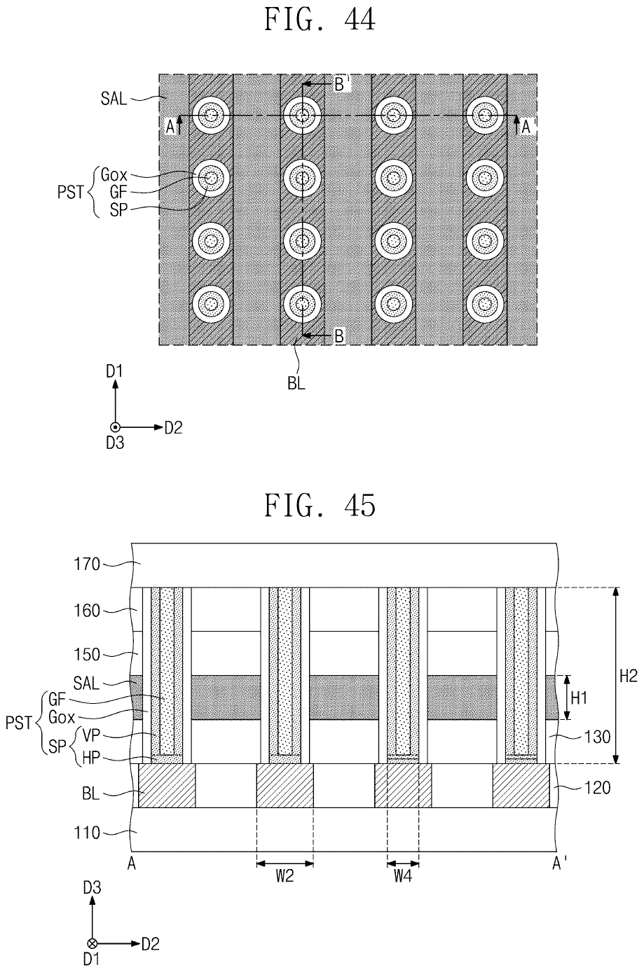

Referring to FIGS. 44, 45, and 46, after the formation of the gate insulating pattern Gox, the semiconductor pattern SP and the center insulating pattern GF may be formed on the upper surface (e.g., the top surface) of each of the bit lines BL to cover the vertical holes TR2, and the gate insulating pattern Gox, the semiconductor pattern SP, and the center insulating pattern GF may form each of the pillar structures PST.

In some embodiments, the semiconductor layer PSP may be formed to fully fill the vertical holes TR2 provided with the gate insulating pattern Gox. For example, the center insulating pattern GF may be omitted.

After the formation of the semiconductor pattern SP and the center insulating pattern GF, an oxygen annealing process may be performed.

After the oxygen annealing process, the seventh insulating layer 170 may be formed on (e.g., to cover or overlap) the pillar structures PST and the sixth insulating layer 160.

Referring to FIGS. 47 and 48, after the formation of the seventh insulating layer 170, trenches TR3 may be formed to extend into (e.g., extend through or penetrate) the fifth, sixth, and seventh insulating layers 150, 160, and 170 and the sacrificial layer SAL. Each of the trenches TR3 may be extended in the second direction D2, between the pillar structures PST, which are adjacent to each other in the first direction D1. The trenches TR3 may be spaced apart from each other in the first direction D1. The trench TR3 may be formed to expose side surfaces of the fifth, sixth, and seventh insulating layers 150, 160, and 170 and the sacrificial layer SAL and a portion of an upper surface (e.g., a top surface) of the third insulating layer 130 to the outside.

Due to the formation of the trenches TR3, each of the fifth, sixth, and seventh insulating layers 150, 160, and 170 and the sacrificial layer SAL may be divided into a plurality of portions, which are spaced apart from each other in the first direction D1.

The trenches TR3 may not be overlapped with the pillar structures PST in the third direction D3, and thus, the pillar structures PST may not be exposed to the outside through the trenches TR3.

The trenches TR3 may be formed by patterning the fifth, sixth, and seventh insulating layers 150, 160, and 170 and the sacrificial layer SAL.

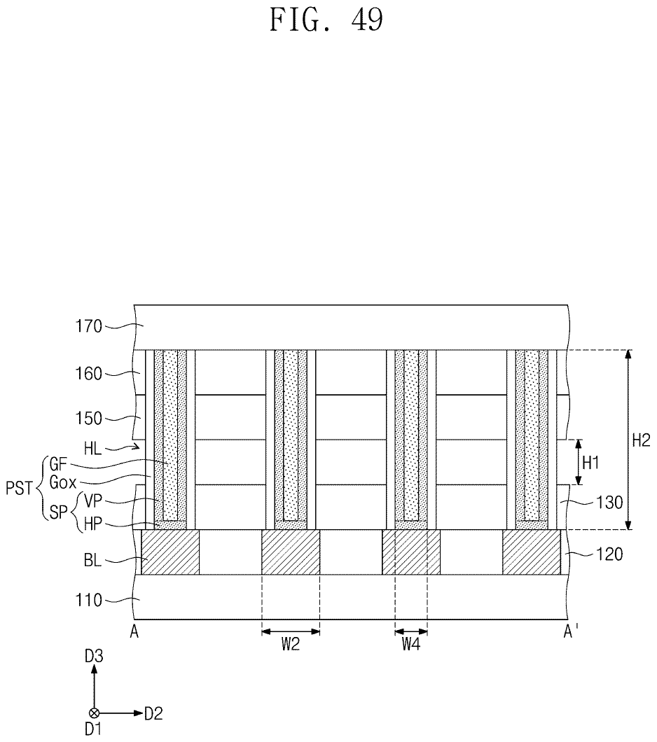

Referring to FIGS. 49 and 50, after the formation of the trenches TR3, a word line region HL may be formed by removing the sacrificial layer SAL through the trenches TR3. The sacrificial layer SAL may be removed through a selective wet etching process.

During this process, the pillar structures PST may support the fifth, sixth, and seventh insulating layers 150, 160, and 170.

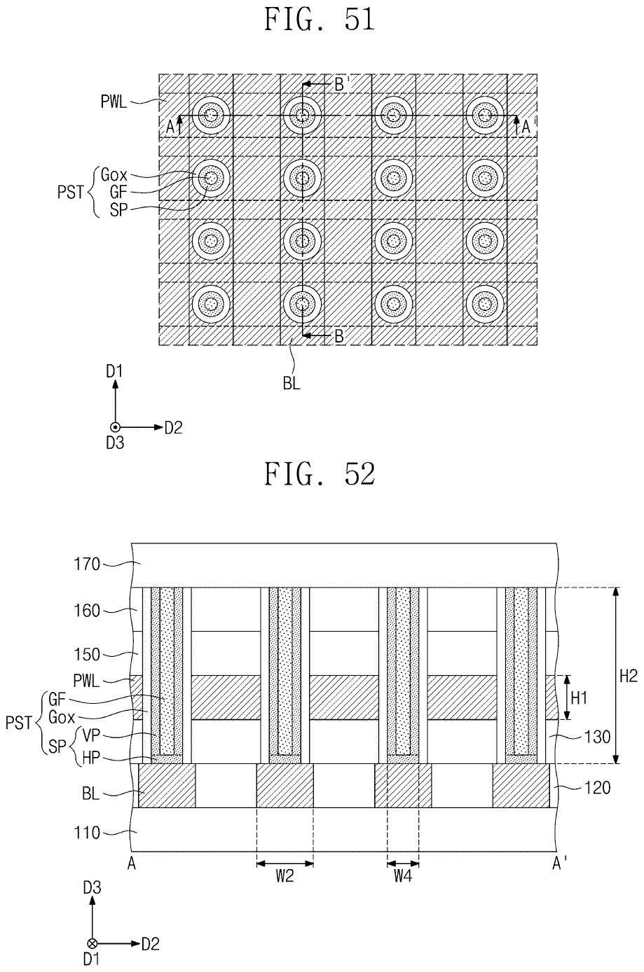

Referring to FIGS. 51, 52, and 53, after the formation of the word line region HL, a preliminary word line layer PWL may be formed to (at least partially) fill the word line region HL and the trenches TR3. The formation of the preliminary word line layer PWL may include performing a deposition process to form a word line metal layer (not shown) filling the word line region HL and the trenches TR3 and on (e.g., covering or overlapping) the upper surface (e.g., the top surface) of the seventh insulating layer 170 and performing a planarization process on the word line metal layer (not shown) to expose the upper surface (e.g., the top surface) of the seventh insulating layer 170, and here, the remaining portion of the word line metal layer (not shown) may form the preliminary word line layer PWL.

In an embodiment, the word line metal layer (not shown) and the preliminary word line layer PWL may be deposited by a physical vapor deposition (PVD) process, a chemical vapor deposition (CVD) process, and/or an atomic layer deposition (ALD) process. The word line metal layer (not shown) may be removed through a chemical mechanical polishing (CMP) process.

The word line metal layer (not shown) and the preliminary word line layer PWL may include a conductive material. The word line metal layer (not shown) and a preliminary word line layer PWL may be formed to have a single-or multi-layered structure. As an example, the word line metal layer PWL and the preliminary word line layer (not shown) may be formed of or include metallic materials (e.g., Ti, Mo, W, Cu, Al, Ta, Ru, Ir, and/or Co), metal silicide materials (e.g., silicide materials containing Ti, Mo, W, Cu, Al, Ta, Ru, Ir, and/or Co), and/or metal nitride materials (e.g., nitride materials containing Ti, Mo, W, Cu, Al, Ta, Ru, Ir, and/or Co).

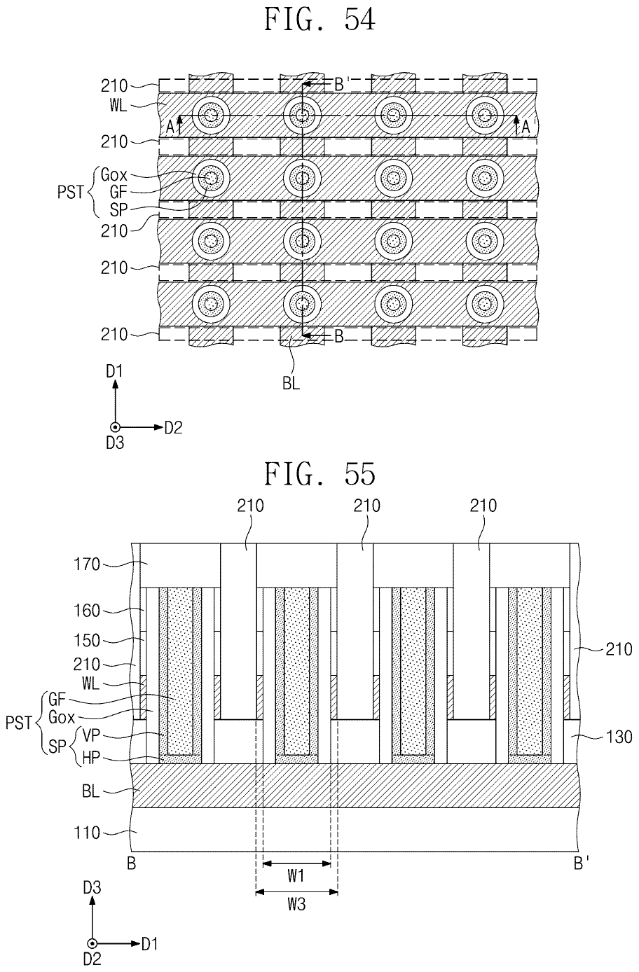

Referring to FIGS. 54 and 55, after the formation of the preliminary word line layer PWL, the word lines WL may be formed by removing a portion of the preliminary word line layer PWL in the trenches TR3. In detail, the side surfaces of the fifth, sixth, and seventh insulating layers 150, 160, and 170 and the upper surface (e.g., the top surface) of the third insulating layer 130 may be exposed by etching the preliminary word line layer PWL through an isotropic etching process. Remaining portions of the preliminary word line layer PWL, which are left after the etching process, may form the word lines WL. Opposite side surfaces of the word lines WL may be exposed to the outside through the isotropic etching process.

After the formation of the word lines WL, the first isolation insulating layers 210 may be formed to be on (e.g., to cover or overlap) the side surfaces of the fifth, sixth, and seventh insulating layers 150, 160, and 170, the upper surface (e.g., the top surface) of the third insulating layer 130, and opposite side surfaces of the word lines WL. The first isolation insulating layers 210 may be formed through a deposition process.

Referring to FIGS. 8 and 9, after the formation of the first isolation insulating layers 210, the storage node contact BC may be formed in the seventh insulating layer 170.

After the formation of the storage node contact BC, the landing pad LP may be formed on the storage node contact BC, and the data storage pattern DSP may be formed on the landing pad LP.

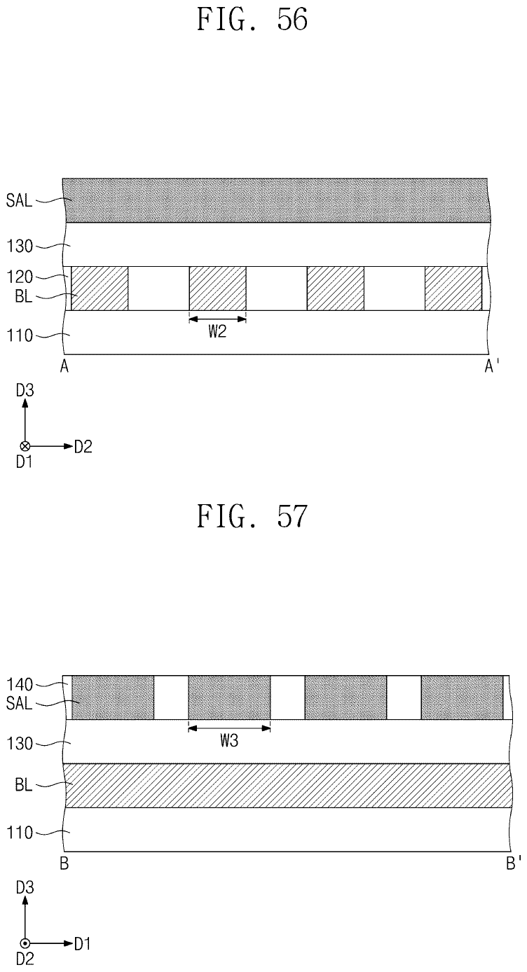

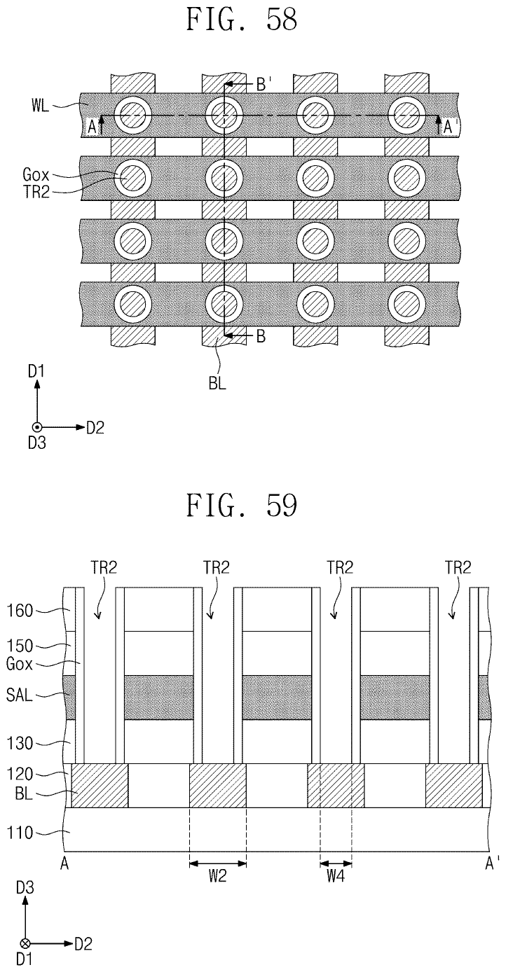

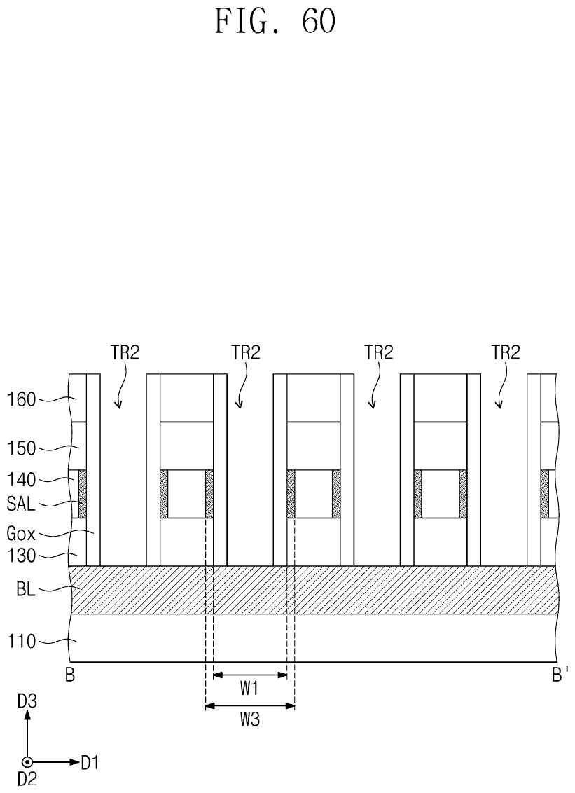

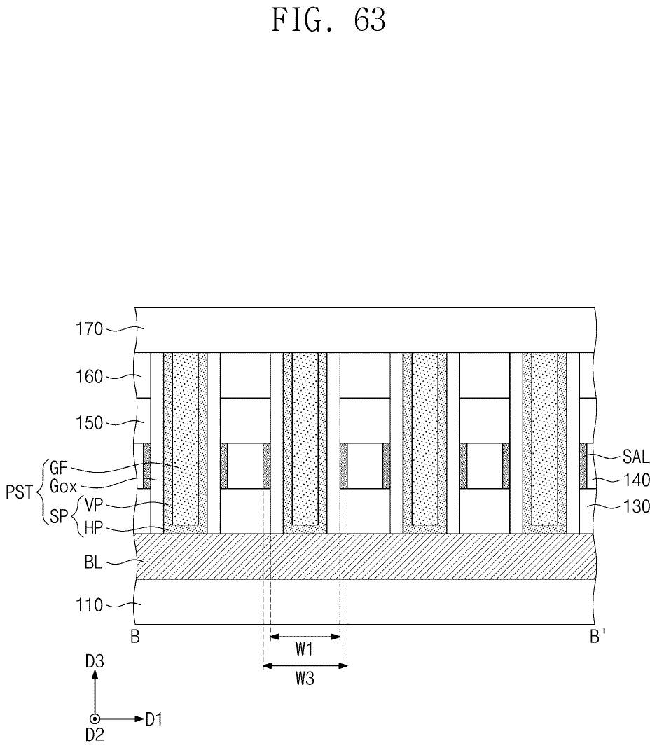

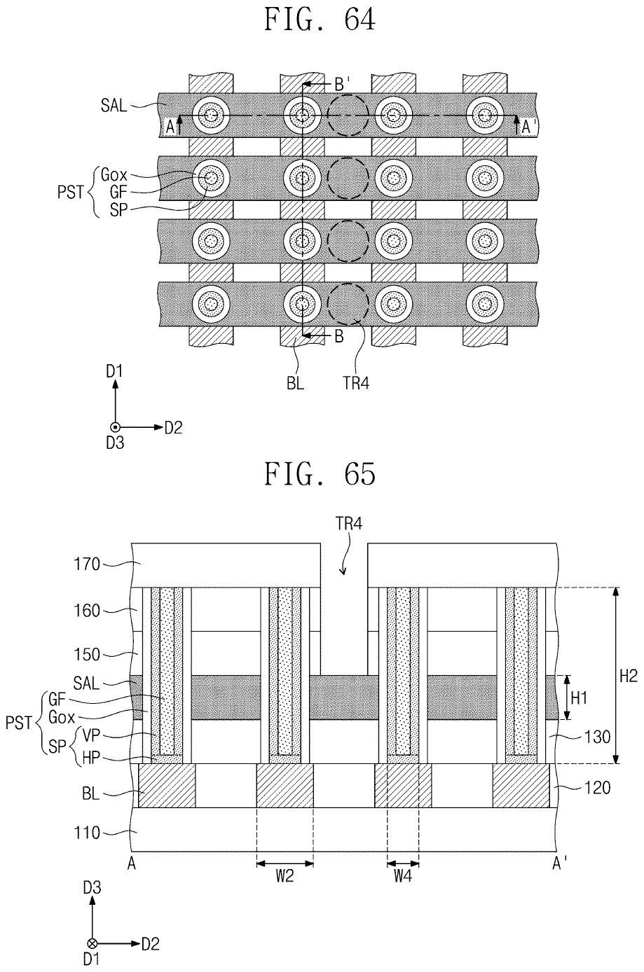

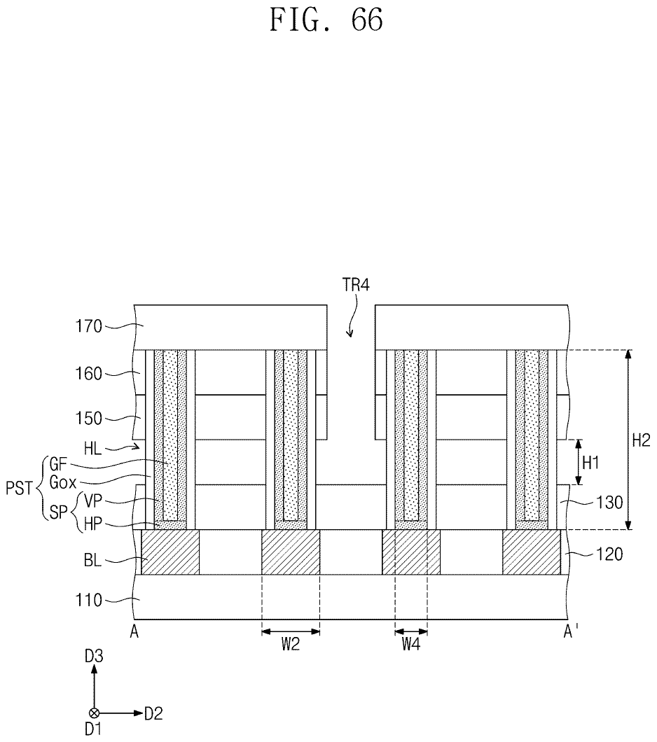

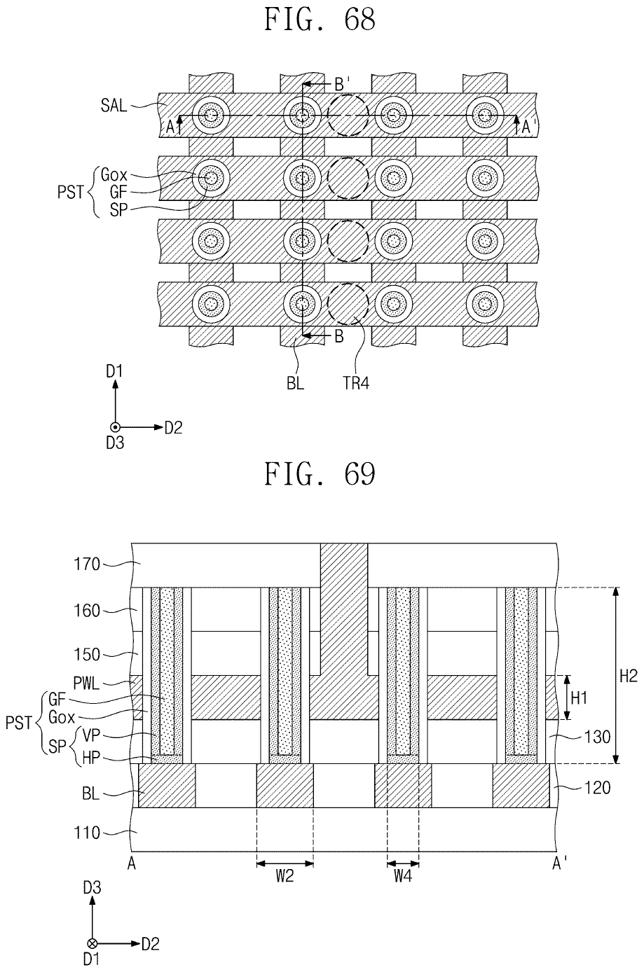

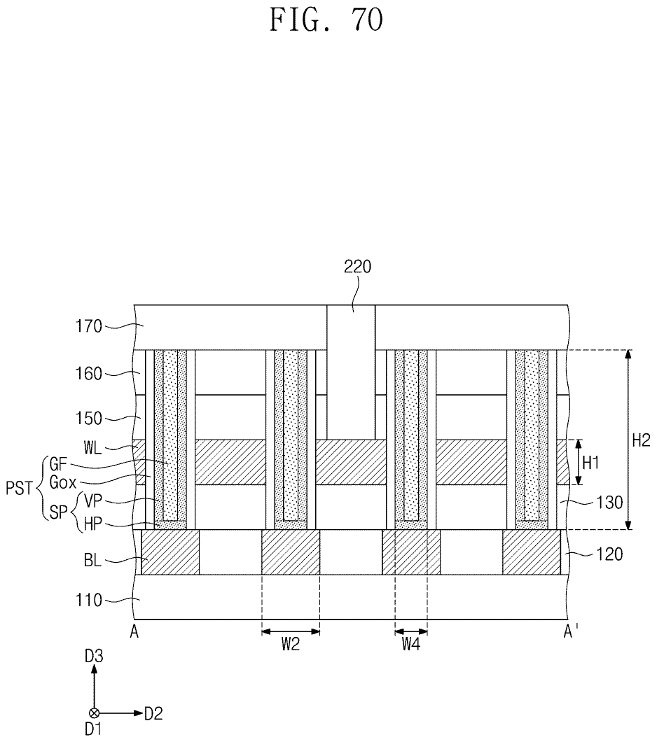

FIGS. 56 to 70 are diagrams illustrating a method of fabricating a semiconductor device, according to an embodiment of the inventive concept. More specifically, FIGS. 58, 61, 64, and 68 is plan views illustrating a semiconductor device according to an embodiment of the inventive concept. FIGS. 56, 59, and 62 are sectional views corresponding to lines A-A′ of FIGS. 10, 58, and 61, respectively. FIGS. 65 and 66 are sectional views corresponding to a line A-A′ of FIG. 64. FIGS. 69 and 70 are sectional views corresponding to a line A-A′ of FIG. 68. FIGS. 57, 60, 63, and 67 are sectional views corresponding to lines B-B′ of FIGS. 10, 58, 61, and 64, respectively.

Processes to be performed after forming the third insulating layer 130 of FIGS. 22 and 23 will be described below. The processes of FIGS. 22 and 23 may be performed in advance.

Referring to FIGS. 56 and 57, after the formation of the third insulating layer 130 described with reference to FIGS. 22 and 23, sacrificial patterns SAL may be formed on the third insulating layer 130. The sacrificial patterns SAL on the upper surface (e.g., the top surface) of the third insulating layer 130 may be extended in the second direction D2. The sacrificial patterns SAL may be spaced apart from each other in the first direction D1.

In some embodiments, the sacrificial patterns SAL may be formed through an epitaxial growth process. In some embodiments, the formation of the sacrificial patterns SAL may include depositing a preliminary sacrificial layer (not shown) on the third insulating layer 130 and patterning the preliminary sacrificial layer (not shown) to form the sacrificial patterns SAL as remaining portions of the preliminary sacrificial layer.

The preliminary sacrificial layer (not shown) and the sacrificial patterns SAL may be formed to have an etch selectivity with respect to the third insulating layer 130.

After the formation of the sacrificial patterns SAL, the fourth insulating layer 140 may be formed to (at least partially) fill a space between adjacent ones of the sacrificial patterns SAL. In an embodiment, the fourth insulating layer 140 may be formed by depositing an insulating material and planarizing the insulating material.

Referring to FIGS. 58, 59, and 60, after the formation of the fourth insulating layer 140, the fifth insulating layer 150 and the sixth insulating layer 160 may be sequentially stacked on the fourth insulating layer 140 and the sacrificial patterns SAL.

After the sequential stacking of the fifth and sixth insulating layers 150 and 160, the vertical holes TR2 may be formed to extend into (e.g., extend through or penetrate) the third, fifth, and sixth insulating layers 130, 150, and 160 and the sacrificial patterns SAL. The vertical holes TR2 may be formed to expose portions of the upper surfaces (e.g., the top surfaces) of the bit lines BL and the inner side surfaces of the vertical holes TR2 to the outside.

After the formation of the vertical holes TR2, the gate insulating patterns Gox may be formed on the inner side surfaces of the vertical holes TR2.

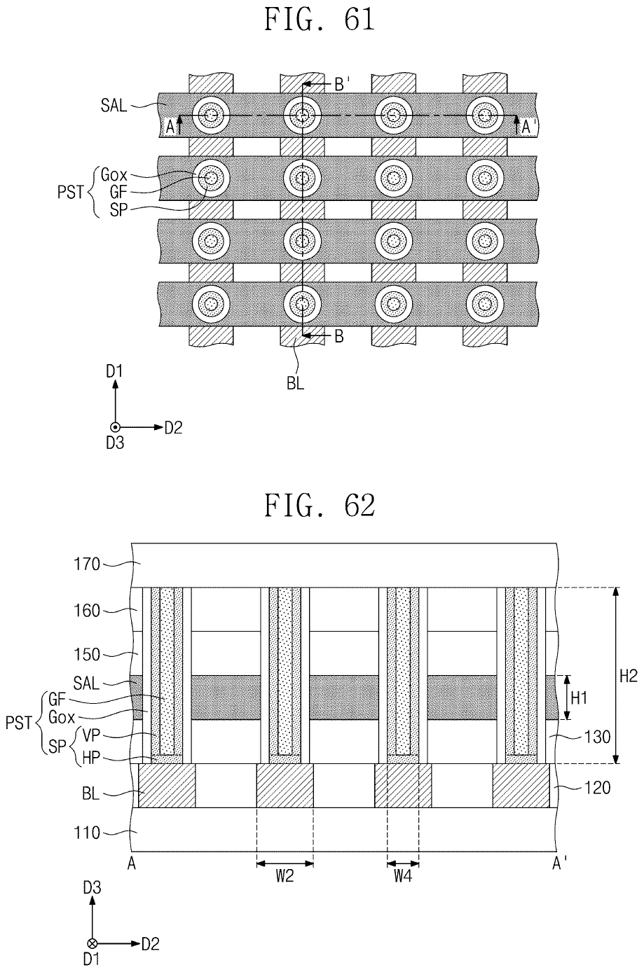

Referring to FIGS. 61, 62, and 63, after the formation of the gate insulating pattern Gox, the semiconductor patterns SP and the center insulating patterns GF may be formed on the exposed upper surfaces (e.g., top surfaces) of the bit lines BL to (at least partially) fill the vertical holes TR2, respectively, and here, the gate insulating pattern Gox, the semiconductor pattern SP, and the center insulating pattern GF may constitute each of the pillar structures PST.

In some embodiments, the semiconductor layer PSP may be formed to fully fill the vertical holes TR2 provided with the gate insulating pattern Gox. For example, the center insulating pattern GF may be omitted.

After the formation of the semiconductor pattern SP and the center insulating pattern GF, an oxygen annealing process may be performed.

After the oxygen annealing process, the seventh insulating layer 170 may be formed on (e.g., to cover or overlap) the pillar structures PST and the sixth insulating layer 160.

Referring to FIGS. 64 and 65, after the formation of the seventh insulating layer 170, openings TR4 may be formed between the pillar structures PST, which are adjacent to each other in the second direction D2. The openings TR4 may be overlapped with the sacrificial patterns SAL in the third direction D3, respectively. The openings TR4 may expose portions of the upper surfaces (e.g., the top surfaces) of the sacrificial patterns SAL and the side surfaces of the fifth, sixth, and seventh insulating layers 150, 160, and 170 to the outside. Each of the openings TR4 may be extended in the third direction D3, on the sacrificial patterns SAL. Each of the openings TR4 may have a circular, elliptical, or polygonal shape, when viewed in a sectional view, but the inventive concept is not limited to this example.

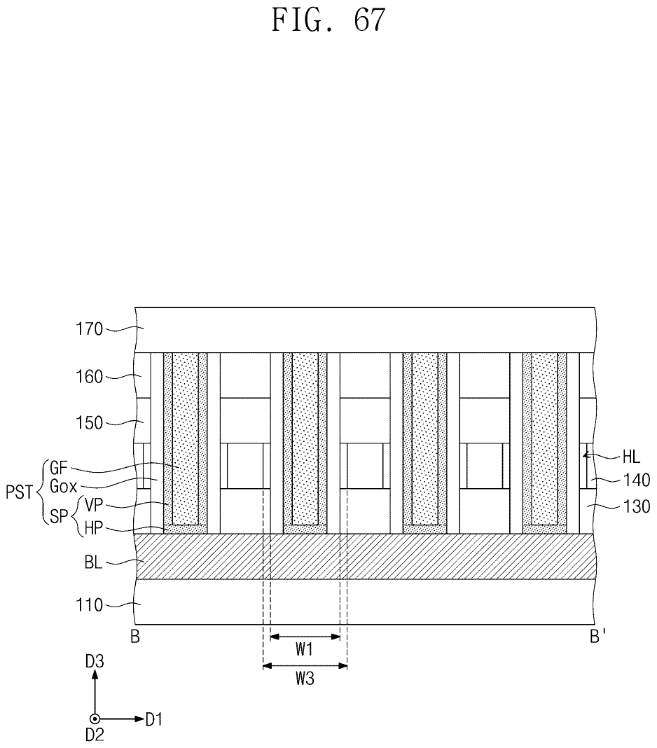

Referring to FIGS. 66 and 67, after the formation of the openings TR4, all of the sacrificial patterns SAL may be removed through the openings TR4, and the word line regions HL may be formed in empty regions which are formed by removing the sacrificial patterns SAL. The upper surface (e.g., the top surface) of the third insulating layer 130 and the side surface of the fourth insulating layer 140 may be exposed to the outside through the word line regions HL. In an embodiment, the sacrificial patterns SAL may be removed through a selective wet etching process.

Referring to FIGS. 68 and 69, after the formation of the word line regions HL, the preliminary word line layer PWL may be formed to (at least partially) fill the word line regions HL and the openings TR4. The formation of the preliminary word line layer PWL may include forming a word line metal layer (not shown) through a deposition process to (at least partially) fill the word line regions HL and the openings TR4 and to be on (e.g., to cover or overlap) the upper surface (e.g., the top surface) of the seventh insulating layer 170 and removing a portion of the word line metal layer (not shown) to expose the upper surface (e.g., the top surface) of the seventh insulating layer 170.

Referring to FIG. 70, after the formation of the preliminary word line layer PWL, the word lines WL may be formed by removing a portion of the preliminary word line layer PWL. In detail, an anisotropic etching process may be performed on the preliminary word line layer PWL to expose the side surfaces of the fifth, sixth, and seventh insulating layers 150, 160, and 170 and the upper surfaces (e.g., the top surfaces) of the word lines WL. Remaining portions of the preliminary word line layer PWL, which are left after the etching process, may form the word lines WL. As a result of the anisotropic etching process, opposite side surfaces of the word lines WL may be exposed to the outside.

After the formation of the word lines WL, the second isolation insulating layers 220 may be formed to be on (e.g., to cover or overlap) the side surfaces of the fifth, sixth, and seventh insulating layers 150, 160, and 170 and the upper surfaces (e.g., the top surfaces) of the word lines WL. The second isolation insulating layers 220 may be formed through a deposition process.

Referring to FIGS. 10 and 11, after the formation of the second isolation insulating layers 220, the storage node contact BC may be formed in the seventh insulating layer 170.

After the formation of the storage node contact BC, the landing pad LP may be formed on the storage node contact BC, and the data storage pattern DSP may be formed on the landing pad LP.

According to an embodiment of the inventive concept, a semiconductor device may include an oxide semiconductor material, which is formed after forming a gate insulating pattern, and it may reduce (e.g., prevent) hydrogen atoms, which are produced in a process of depositing the gate insulating pattern, from entering the oxide semiconductor material. In addition, since the gate insulating pattern, the oxide semiconductor material, and a center insulating pattern are sequentially deposited, at least a portion of (e.g., most of) the surface of the oxide semiconductor material may be encompassed (at least partially surrounded) by the gate insulating pattern and the center insulating pattern, after the deposition of the center insulating pattern, and thus, it may reduce an area of the oxide semiconductor material exposed to the outside. Thus, when the oxide semiconductor material is exposed to a hydrogen gas in a subsequent deposition process, it may reduce the amount of hydrogen entering the oxide semiconductor material and to reduce (e.g., prevent) the device deterioration caused by the hydrogen entering the oxide semiconductor material. Accordingly, the reliability and electrical characteristics of the semiconductor device may be improved.

Furthermore, in the semiconductor device according to an embodiment of the inventive concept, since the oxide semiconductor material is interposed the center insulating pattern and the gate insulating pattern containing oxide, it may increase the efficiency of an oxygen annealing process through an upper surface (e.g., a top surface) of the oxide semiconductor material. Accordingly, a process time for the oxygen annealing process, which is a high-temperature process, may be reduced, and it may prevent or suppress a metal oxide from being formed between a bit line and the oxide semiconductor material by the oxygen annealing process. Thus, a contact resistance between the bit line and the oxide semiconductor material may be lowered, when compared to the case where the oxide semiconductor material is not formed between the center insulating pattern and the gate insulating pattern, and thus, the reliability and electrical characteristics of the semiconductor device may be improved.

While example embodiments of the inventive concept have been particularly shown and described, it will be understood by one of ordinary skill in the art that variations in form and detail may be made therein without departing from the scope of the attached claims.

What is claimed is:

1. A semiconductor device, comprising:
a substrate;
a bit line on the substrate, wherein the bit line extends in a first direction that is parallel with an upper surface of the substrate;
a word line on the bit line, wherein the word line extends in a second direction that is parallel with the upper surface of the substrate and intersects the first direction;
a pillar structure on the bit line, wherein the pillar structure extends through the word line and comprises a semiconductor pattern and a gate insulating pattern between the semiconductor pattern and the word line; and
a data storage pattern on the pillar structure,
wherein the semiconductor pattern comprises a horizontal portion and a vertical portion,
wherein the horizontal portion is adjacent to the bit line,
wherein the vertical portion is on the horizontal portion and extends in a third direction that is perpendicular to the upper surface of the substrate, and
wherein the semiconductor pattern has a hollow pillar shape.

2. The semiconductor device of claim 1, wherein the word line extends around the pillar structure.

3. The semiconductor device of claim 1, wherein the pillar structure further comprises a center insulating pattern, and
wherein the vertical portion extends around the center insulating pattern.

4. The semiconductor device of claim 3, wherein the center insulating pattern is in contact with an upper surface of the horizontal portion.

5. The semiconductor device of claim 3, wherein a lower surface of the center insulating pattern is closer than a lower surface of the word line to the upper surface of the substrate.

6. The semiconductor device of claim 3, wherein the center insulating pattern comprises silicon oxide and/or metal oxide.

7. The semiconductor device of claim 1, wherein an upper surface of the horizontal portion is closer than a lower surface of the word line to the upper surface of the substrate.

8. The semiconductor device of claim 1, wherein a width of the pillar structure in the first direction is less than a width of the word line in the first direction.

9. The semiconductor device of claim 1, wherein a width of the horizontal portion in the second direction is less than a width of the bit line in the second direction.

10. The semiconductor device of claim 1, wherein a length of the pillar structure in the third direction is greater than a length of the word line in the third direction.

11. The semiconductor device of claim 1, wherein the semiconductor pattern comprises oxygen (O) and two or more elements that are selected from indium (In), gallium (Ga), tin (Sn), aluminum (AL), and zinc (Zn).

12. A semiconductor device, comprising:
a substrate;
a bit line on the substrate, wherein the bit line extends in a first direction that is parallel with an upper surface of the substrate;
a word line on the bit line, wherein the word line extends in a second direction that is parallel with the upper surface of the substrate and intersects the first direction;
a pillar structure on the bit line, wherein the pillar structure extends through the word line in a third direction that is perpendicular to the upper surface of the substrate; and
a data storage pattern on the pillar structure,
wherein the pillar structure comprises a center insulating pattern, a semiconductor pattern that extends around the center insulating pattern, and a gate insulating pattern that extends around the semiconductor pattern.

13. The semiconductor device of claim 12, wherein the semiconductor pattern comprises horizontal portion and a vertical portion,
wherein the horizontal portion is between the center insulating pattern and the bit line and
wherein the vertical portion is between the center insulating pattern and the gate insulating pattern.

14. The semiconductor device of claim 13, wherein the bit line, the horizontal portion, and the center insulating pattern overlap each other in the third direction.

15. The semiconductor device of claim 12, wherein the center insulating pattern comprises oxygen.

16. The semiconductor device of claim 12, wherein a lower surface of the center insulating pattern is closer than a lower surface of the word line to the upper surface of the substrate.

17. The semiconductor device of claim 12, wherein a width of the word line in the first direction is greater than a width of the pillar structure in the first direction.

18. The semiconductor device of claim 13, wherein a width of the bit line in the second direction is greater than a width of the horizontal portion in the second direction.

19. The semiconductor device of claim 12, wherein a length of the pillar structure in the third direction is greater than a length of the word line in the third direction.

20. A semiconductor device, comprising:
a bit line on a substrate, wherein the bit line extends in a first direction that is parallel with an upper surface of the substrate;
a word line extending in a second direction that is parallel with the upper surface of the substrate, wherein the second direction intersects the first direction, and wherein the word line is spaced apart from the bit line in a third direction that is perpendicular to the upper surface of the substrate;
a pillar structure extending into the word line in the third direction, wherein the pillar structure comprises a center insulating pattern, a semiconductor pattern that extends around the center insulating pattern, and a gate insulating pattern that extends around the semiconductor pattern;
a landing pad on the pillar structure;
a storage node contact between the landing pad and the semiconductor pattern; and
a data storage pattern on the landing pad,
wherein the semiconductor pattern comprises a horizontal portion between the center insulating pattern and the bit line and a vertical portion between the center insulating pattern and the gate insulating pattern.
